(19) United States
(12) Patent Application Publication
(10) Pub. No.: US 2026/0231581 A1
(43) Pub. Date: Aug. 6, 2026

(54) DISPLAY APPARATUS AND ELECTRONIC DEVICE INCLUDING THE SAME

(71) Applicant: Samsung Display Co., LTD., Yongin-si (KR)

(72) Inventors: Woosuk SEO, Yongin-si (KR); Hyelan KIM, Yongin-si (KR); Hyungsoo YOON, Yongin-si (KR); Gyujeong LEE, Yongin-si (KR)

(21) Appl. No.: 19/416,331

(22) Filed: Dec. 11, 2025

(30) Foreign Application Priority Data
Jan. 31, 2025 (KR) 10-2025-0012634

(51) Int. Cl. H10H 29/49; H10H 29/32

(52) U.S. Cl. CPC H10H 29/49; H10H 29/32

(57) ABSTRACT

A display apparatus includes a display area and a non-display area surrounding the display area. The display apparatus includes island portions spaced apart from each other in a first direction and a second direction intersecting the first direction in the display area and in which light-emitting elements arranged; bridge portions connecting two adjacent island portions among the island portions to each other; and a connection wiring disposed on at least one bridge portion among the bridge portions, wherein the connection wiring has a structure in which a first barrier layer, a first conductive layer disposed on the first barrier layer, and a second barrier layer disposed on the first conductive layer are stacked, and each of the first barrier layer and the second barrier layer includes an amorphous alloy.

This application claims priority to Korean Patent Application No. 10-2025-0012634, filed on January 31, 2025, and all the benefits accruing therefrom under 35 U.S.C. §119, the content of which in its entirety is herein incorporated by reference.

### BACKGROUND

### Technical Field

One or more embodiments relate to a display apparatus and an electronic apparatus including the display apparatus.

### BACKGROUND ART

In general, along with the development of display panels that visually display electrical signals, various display apparatuses having characteristics such as a slim profile, light weight, and low power consumption and electronic apparatuses including such display apparatuses have been introduced. For example, flexible display apparatuses which may be folded or rolled, display apparatuses of various structures (such as, stretchable display apparatuses), and electronic apparatuses including such display apparatuses have been actively researched and developed.

### SUMMARY

### Technical Problem

One or more embodiments include a display apparatus having improved stretchability and capable of implementing excellent quality images even when stretched and an electronic apparatus including the display apparatus. However, aspects of embodiments are not limited thereto, and the above characteristics do not limit the scope of embodiments according to the disclosure.

### Solution to Problem

An embodiment of the disclosure provides a display apparatus including a display area and a non-display area surrounding the display area, the display apparatus includes island portions spaced apart from each other in a first direction and a second direction intersecting the first direction in the display area, and including light-emitting elements arranged in the island portions; bridge portions connecting two adjacent island portions among the island portions to each other; and a connection wiring disposed on at least one bridge portion among the bridge portions, where the connection wiring has a structure in which a first barrier layer, a first conductive layer disposed on the first barrier layer, and a second barrier layer disposed on the first conductive layer are stacked, and each of the first barrier layer and the second barrier layer includes an amorphous alloy.

According to an embodiment, the amorphous alloys included in the first barrier layer and the second barrier layer may include at least one of aluminum (Al), silicon (Si), titanium (Ti), cobalt (Co), nickel (Ni), copper (Cu), yttrium (Y), zirconium (Zr), or molybdenum (Mo).

According to an embodiment, the amorphous alloys included in the first barrier layer and the second barrier layer may include a binary to quaternary alloy composition having one of titanium (Ti), molybdenum (Mo), zirconium (Zr), and aluminum (Al) as a main element.

According to an embodiment, the amorphous alloys included in the first barrier layer and the second barrier layer include at least one of Ti₆₅Zr₁₆Si₁₅Mo₄, Mo₅₂Zr₂₆Si₁₂Ti₁₀, Zr₇₄Cu₂₀Co₆, Zr_{87.5}Cu₅Si_{7.5}, Al₈₅Y₈Ni₅Co₂, or Al₉₀Y₁₀.

According to an embodiment, the first conductive layer may have a structure in which a first sublayer and a second sublayer are alternately stacked, the first sublayer may include an amorphous alloy, and the second sublayer may include a crystalline metal.

According to an embodiment, the first sublayer and the second sublayer may include materials based on same metals.

According to an embodiment, the first sublayer may include an alloy of aluminum and a rare earth element, and the second sublayer may include aluminum.

According to an embodiment, the rare earth element may include at least one of yttrium (Y), samarium (Sm), cerium (Ce), or lanthanum (La).

According to an embodiment, the total number of first sublayers and second sublayers included in the first conductive layer may be an odd number.

According to an embodiment, an upper surface of the first barrier layer may contact the first sublayer, and a lower surface of the second barrier layer may contact the first sublayer.

According to an embodiment, the display apparatus may further include a pixel driving circuit portion arranged on at least one island portion among the island portions and electrically connected to the light-emitting element; and a connection electrode configured to connect the pixel driving circuit portion to the light-emitting element, and at least one of a source electrode and a drain electrode of the pixel driving circuit portion, or the connection electrode may include a different material from the connection wiring.

According to an embodiment, at least one of the source electrode, the drain electrode, or the connection electrode may have a structure in which a third barrier layer, a second conductive layer on the third barrier layer, and a fourth barrier layer on the second conductive layer are stacked, and the third barrier layer, the second conductive layer, and the fourth barrier layer may be crystalline metal layers.

According to an embodiment, each of the third barrier layer, the second conductive layer, and the fourth barrier layer may be a single layer composed of a single element.

Another embodiment of the disclosure provides a display apparatus including a display area and a non-display area surrounding the display area, the display apparatus includes island portions spaced apart from each other in the display area, and each of which including a pixel driving circuit portion and a light-emitting element electrically connected to the pixel driving circuit portion, where the pixel driving circuit portion and the light-emitting element are arranged in the island portions; bridge portions connecting two adjacent island portions among the island portions to each other; a connection wiring disposed on at least one bridge portion among the bridge portions; and a connection electrode disposed on at least one island portion among the island portions and configured to connect the corresponding pixel driving circuit portion to the corresponding light-emitting element, where the connection wiring has a structure in which a first barrier layer, a first conductive layer, and a second barrier layer are stacked, the connection electrode has a structure in which a third barrier layer, a second conductive layer, and a fourth barrier layer are stacked, and the first barrier layer and the second barrier layer of the connection wiring include amorphous alloys, and the third barrier layer and the fourth barrier layer of the connection electrode include crystalline metals.

According to an embodiment, the amorphous alloys included in the first barrier layer and the second barrier layer may include at least one of aluminum (Al), silicon (Si), titanium (Ti), cobalt (Co), nickel (Ni), copper (Cu), yttrium (Y), zirconium (Zr), or molybdenum (Mo).

According to an embodiment, the amorphous alloys included in the first barrier layer and the second barrier layer may include a binary to quaternary alloy composition having one of titanium (Ti), molybdenum (Mo), zirconium (Zr), and aluminum (Al) as a main element.

According to an embodiment, the first conductive layer may have a structure in which a first sublayer and a second sublayer are alternately stacked, the first sublayer may include an amorphous alloy, and the second sublayer may include a crystalline metal.

According to an embodiment, the first sublayer may include an alloy of aluminum and a rare earth element, and the second sublayer may include aluminum.

According to an embodiment, each of the third barrier layer, the second conductive layer, and the fourth barrier layer may be a single layer composed of a single element.

Another embodiment of the disclosure provides an electronic apparatus including a display apparatus configured to provide an image; and a housing in which the display apparatus is accommodated, where the display apparatus includes island portions spaced apart from each other in a first direction and a second direction intersecting the first direction, and including light-emitting elements arranged in the island portions; bridge portions connecting two adjacent island portions among the island portions to each other; and a connection wiring disposed on at least one bridge portion among the bridge portions, the connection wiring has a structure in which a first barrier layer, a first conductive layer disposed on the first barrier layer, and a second barrier layer disposed on the first conductive layer are stacked, and each of the first barrier layer and the second barrier layer includes an amorphous alloy.

### Advantageous Effects of Invention

According to some embodiments of the disclosure, a display apparatus having improved stretchability and implementing quality images, and an electronic apparatus including the display apparatus may be provided. These effects are only examples, and the effects of the disclosure are not limited thereto.

### BRIEF DESCRIPTION OF DRAWINGS

FIG. 1 is a schematic perspective view of a display apparatus according to an embodiment of the disclosure.

FIGS. 2A and 2B are perspective views of the display apparatus of FIG. 1 stretched in a first direction.

FIG. 2C is a perspective view of the display apparatus of FIG. 1 stretched in a second direction.

FIG. 2D is a perspective view of the display apparatus of FIG. 1 stretched in the first direction and the second direction.

FIG. 2E is a perspective view of the display apparatus of FIG. 1 stretched in a third direction.

FIG. 3 is a schematic plan view of a display apparatus according to an embodiment of the disclosure.

FIG. 4A is an enlarged plan view of a region IV of FIG. 3, which is a portion of the display apparatus according to an embodiment of the disclosure.

FIG. 4B is an enlarged plan view of a region IV of FIG. 3, which is a portion of the display apparatus according to an embodiment.

FIG. 4C is an enlarged plan view of a region IV of FIG. 3, which is a portion of the display apparatus according to an embodiment.

FIG. 5 is a schematic cross-sectional view of a first island portion and a first bridge portion arranged in a display area of the display apparatus according to an embodiment of the disclosure.

FIGS. 6A through 6C are equivalent circuit diagrams of a subpixel of a display apparatus according to an embodiment of the disclosure.

FIGS. 7A and 7B are schematic cross-sectional views of a light-emitting element of the display apparatus according to an embodiment;

FIG. 8A is an enlarged plan view of a first island portion of a display apparatus according to an embodiment of the disclosure.

FIG. 8B is a plan view showing an arrangement of wiring on a first bridge portion of a display apparatus according to an embodiment of the disclosure.

FIG. 9 shows a cross-section taken along line I-I' of FIG. 8A and a cross-section taken along line II-II' of FIG. 8B.

FIGS. 10A through 10C are cross-sectional views of a connection wiring of a display apparatus according to an embodiment of the disclosure.

FIG. 11 is a cross-sectional view of a connection electrode of a display apparatus according to an embodiment of the disclosure.

FIG. 12A is a schematic perspective view of an embodiment of an electronic apparatus including a display apparatus according to an embodiment of the disclosure.

FIG. 12B is a block diagram of an electronic apparatus including a display apparatus according to an embodiment of the disclosure.

FIGS. 13A through 13I are schematic perspective views of embodiments of an electronic apparatus including a display apparatus according to an embodiment of the disclosure.

### DETAILED DESCRIPTION

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms "first," "second," etc. may be used herein to describe various components, these components should not be limited by these terms. These components are only used to distinguish one component from another.

As used herein, the singular forms "a," "an," and "the" are intended to include the plural forms as well, unless the context clearly indicates otherwise.

The terms "comprises" and/or "comprising" used herein specify the presence of stated features or components, but do not preclude the presence or addition of one or more other features or components.

It will be understood that when a layer, region, or component is referred to as being "formed on" another layer, region, or component, it can be directly or indirectly formed on the other layer, region, or component. That is, for example, intervening layers, regions, or components may be present.

Sizes of elements in the drawings may be exaggerated or reduced for convenience of explanation. For example, since sizes and thicknesses of components in the drawings are arbitrarily illustrated for convenience of explanation, embodiments are not limited thereto.

When a certain embodiment may be implemented differently, a specific process order may be performed differently from the described order. For example, two consecutively described processes may be performed substantially at the same time or performed in an order opposite to the described order.

It will also be understood that when a layer, region, or component is referred to as being "connected" or "coupled" to another layer, region, or component, it can be directly connected or coupled to the other layer, region, or component or intervening layers, regions, or components may be present. For example, when a layer, region, or component is referred to as being "electrically connected" or "electrically coupled" to another layer, region, or component, it can be directly electrically connected or coupled to the other layer, region, or component or intervening layers, regions, or components may be present.

Throughout the disclosure, the expression "at least one of a, b or c" indicates only a, only b, only c, both a and b, both a and c, both b and c, all of a, b, and c, or variations thereof.

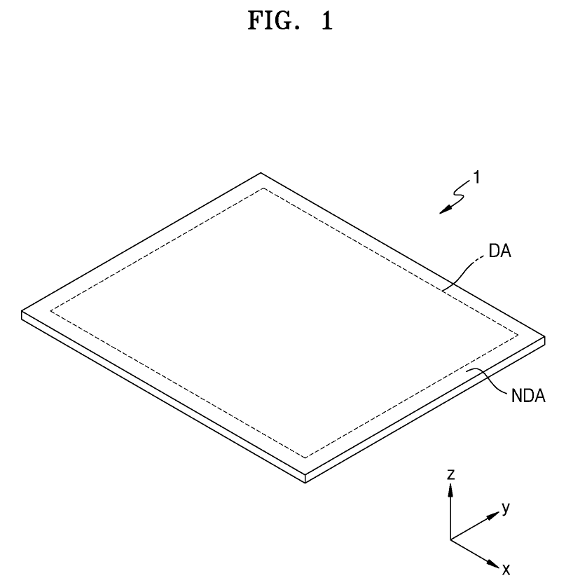

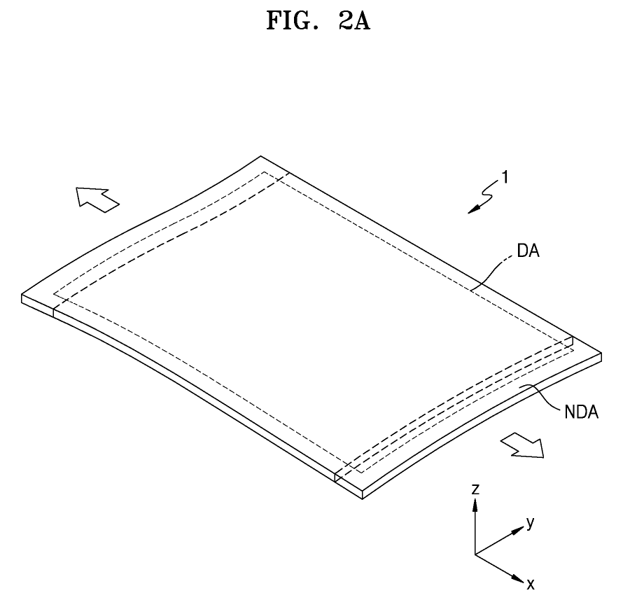

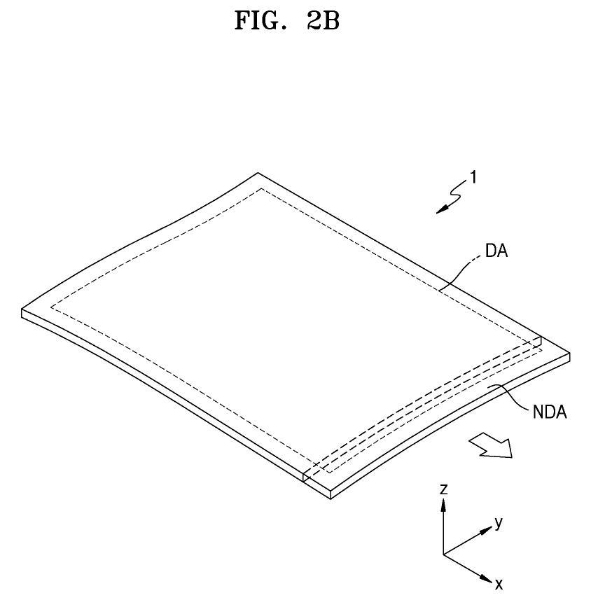

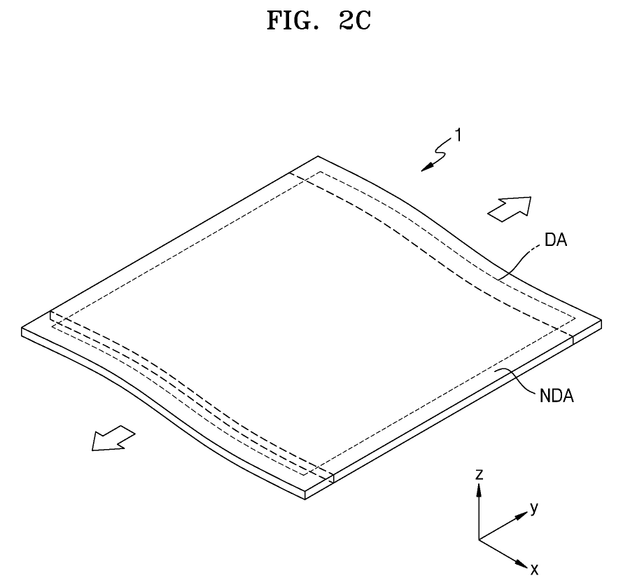

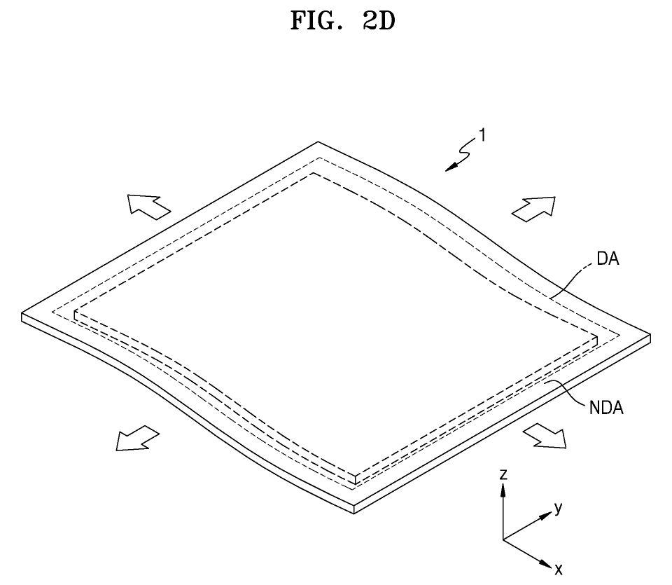

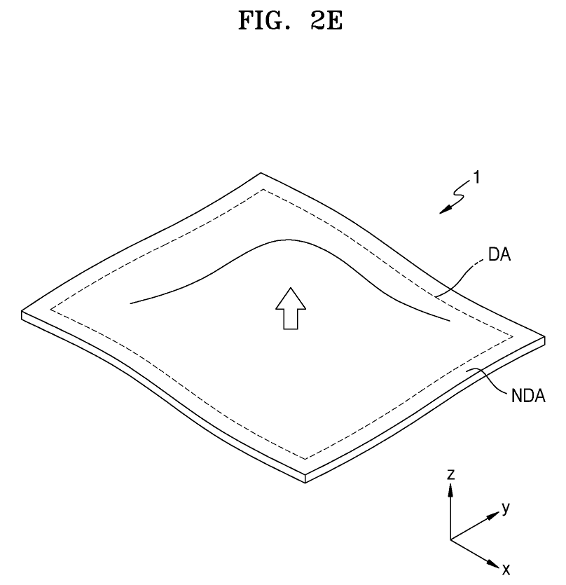

FIG. 1 is a schematic perspective view of a display apparatus 1 according to an embodiment of the disclosure. FIGS. 2A and 2B are perspective views of the display apparatus 1 of FIG. 1 stretched in a first direction. FIG. 2C is a perspective view of the display apparatus 1 of FIG. 1 stretched in a second direction. FIG. 2D is a perspective view of the display apparatus 1 of FIG. 1 stretched in the first direction and the second direction. FIG. 2E is a perspective view of the display apparatus 1 of FIG. 1 stretched in a third direction.

Referring to FIG. 1, the display apparatus 1 may include a display area DA and a non-display area NDA. The display area DA may include a plurality of pixels. The display apparatus 1 may provide an image by using light emitted by the plurality of pixels. The non-display area NDA may be disposed outside the display area DA. The non-display area NDA may entirely surround the display area DA.

The display apparatus 1 may be stretched or shrunk in various directions. The display apparatus 1 may be stretched in the first direction (e.g., an x direction and/or an -x direction) by an external force applied by an external object or a user. According to an embodiment, as shown in FIGS. 2A and 2B, the display area DA and/or the non-display area NDA of the display apparatus 1 may be stretched in the x direction (for example, the x direction and/or the -x direction). For example, as shown in FIG. 2A, the display area DA and/or the non-display area NDA may be stretched in the x direction and the -x direction or may be stretched in the x direction with one side of the display apparatus 1 fixed as shown in FIG. 2B.

The display apparatus 1 may be stretched in the second direction (e.g., a y direction and/or a -y direction) due to an external force exerted by an external object or a user. According to an embodiment, as shown in FIG. 2C, the display area DA and/or the non-display area NDA of the display apparatus 1 may be stretched in the y direction and/or the -y direction. According to another embodiment, the display area DA and/or the non-display area NDA may be stretched in the y direction or the -y direction with one side of the display apparatus 1 fixed.

The display apparatus 1 may be stretched in a plurality of directions, for example, the first direction (e.g., the x direction and/or the -x direction) and the second direction (e.g., the y direction and/or the -y direction) by an external force exerted by an external object or a portion of a human body. As shown in FIG. 2D, the display area DA and/or the non-display area NDA of the display apparatus 1 may be stretched in the ±x direction and the ±y direction.

The display apparatus 1 may be stretched in a third direction (e.g., a z direction or a -z direction) due to an external force exerted by an external object or a portion of a human body. According to an embodiment, it is shown in FIG. 2E that a portion of the display apparatus 1, for example, a partial region of the display area DA, protrudes in the z direction. According to another embodiment, a portion of the display apparatus 1, for example, a partial region of the display area DA, may protrude in the z direction (or may be depressed in the -z direction).

Although it is shown in FIGS. 2A through 2E that the display apparatus 1 is stretched in the first direction, the second direction, and/or the third direction, the disclosure is not limited thereto. According to another embodiment, the display apparatus 1 may be transformed into various irregular shapes such as being bent or twisted along two or more axes.

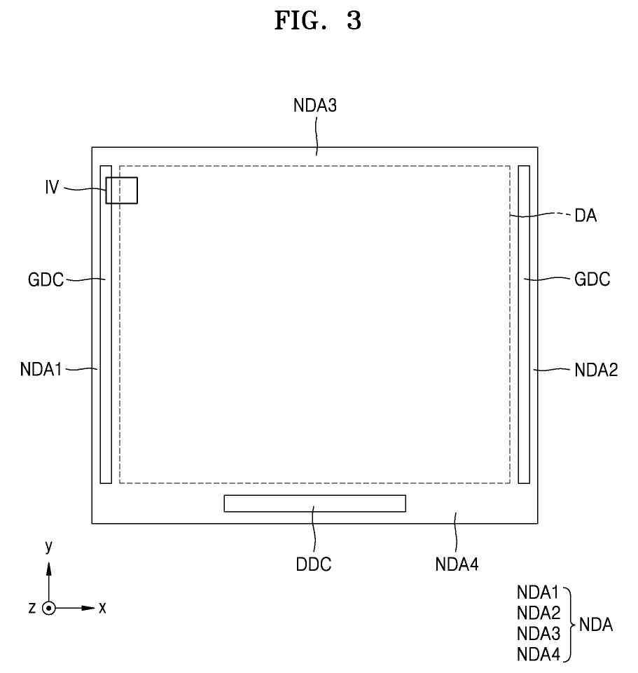

FIG. 3 is a schematic plan view of the display apparatus 1 according to an embodiment of the disclosure. As used herein, the “plan view” is a view in a thickness direction (i.e., z direction) of the display apparatus 1.

A plurality of pixels may be arranged in the display area DA of the display apparatus 1. Each pixel may include sub-pixels configured to emit light of different colors. A light-emitting element corresponding to each sub-pixel may be arranged in the display area DA. A circuit may be located in the non-display area NDA around the display area DA, where the circuit is configured to provide electrical signals to the light-emitting elements arranged in the display area DA and transistors electrically connected to the light-emitting elements. Gate driving circuits GDC may be respectively arranged in a first non-display area NDA1 and a second non-display area NDA2, respectively, arranged on two opposite sides with the display area DA therebetween. The gate driving circuit GDC may include drivers configured to provide electrical signals to respective gate electrodes of the transistors electrically connected to the light-emitting elements. Although it is shown in FIG. 3 that the gate driving circuits GDC are respectively arranged in the first non-display area NDA1 and the second non-display area NDA2, the disclosure is not limited thereto. According to another embodiment, a gate driving circuit GDC may be arranged in one of the first non-display area NDA1 and the second non-display area NDA2.

A data driving circuit DDC may be arranged in a third non-display area NDA3 and/or a fourth non-display area NDA4 each connecting the first non-display area NDA1 to the second non-display area NDA2. According to an embodiment, it is shown in FIG. 3 that the data driving circuit DDC is arranged in the fourth non-display area NDA4. According to another embodiment, data driving circuits DDC may be respectively arranged in the third non-display area NDA3 and the fourth non-display area NDA4.

Although it is shown in FIG. 3 that the data driving circuit DDC is arranged in the fourth non-display area NDA4 of the display apparatus 1, the disclosure is not limited thereto. According to another embodiment, the display apparatus 1 may further include a flexible circuit board (not shown) electrically connected through a terminal portion (not shown) arranged in the fourth non-display area NDA4, and the data driving circuit DDC may be arranged on the flexible circuit board.

According to some embodiments, an elongation of the non-display area NDA may be equal to or less than an elongation of the display area DA. According to an embodiment, the elongation of the non-display area NDA may be different for each region thereof. For example, although the first non-display area NDA1, the second non-display area NDA2, and the third non-display area NDA3 may have substantially the same elongations, an elongation of the fourth non-display area NDA4 may be less than an elongation of each of the first non-display area NDA1, the second non-display area NDA2, and the third non-display area NDA3. In this specification, the elongation is a numerical value representing a change ΔL/L in a length by which the display apparatus 1 is stretchable without a physical damage to the display apparatus 1 when an external force is applied to the display apparatus 1. Here, ΔL represents an amount of change in a length of a display apparatus, and L represents an initial length of the display apparatus.

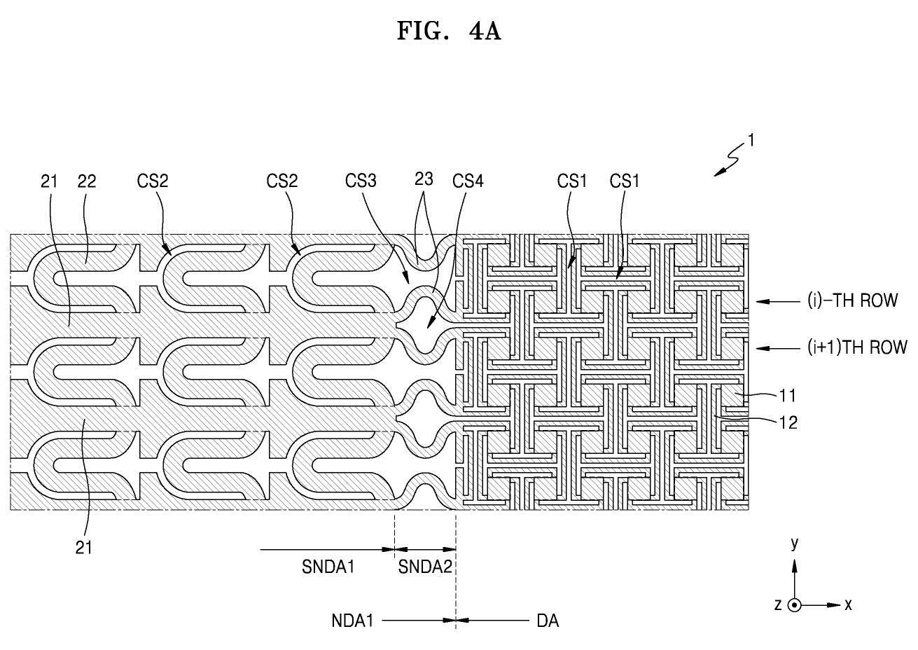

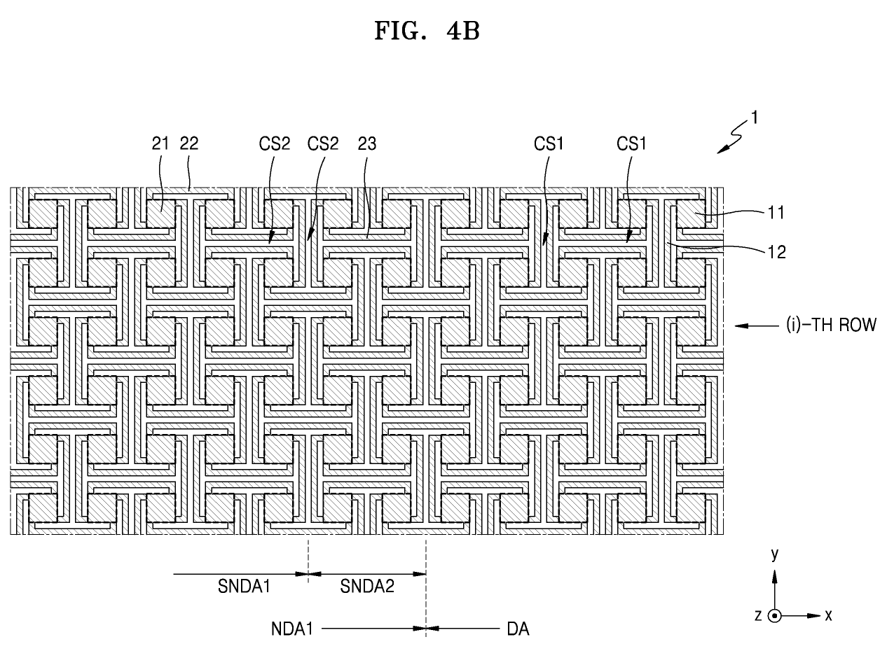

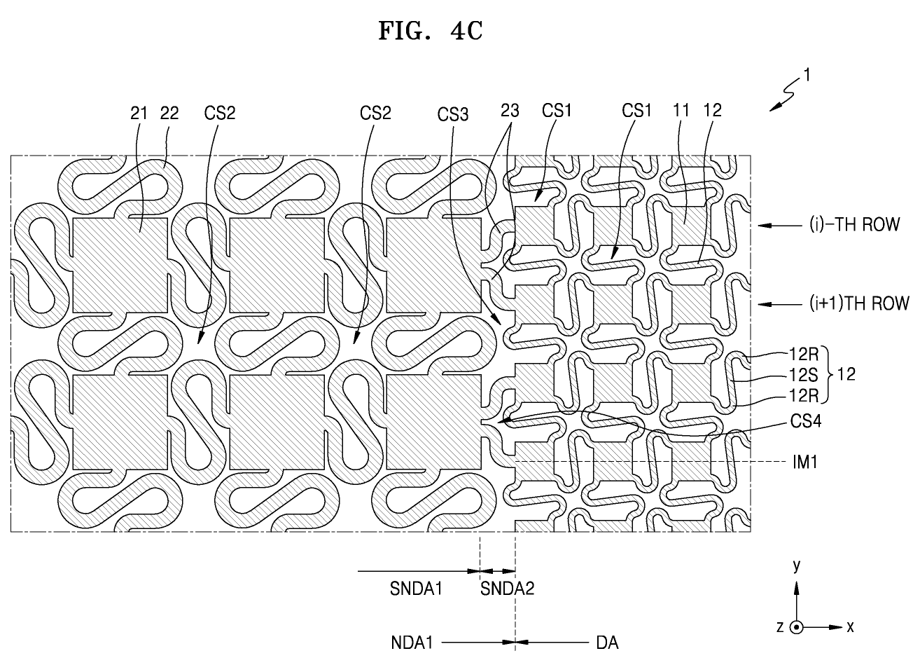

FIG. 4A is an enlarged plan view of a region IV of FIG. 3, which is a portion of the display apparatus 1 according to an embodiment of the disclosure.

Referring to FIG. 4A, the display apparatus 1 may include first island portions 11 and first bridge portions 12 in the display area DA, where the first island portions 11 are apart from each other in the first direction (e.g., the x direction or the -x direction) and the second direction (e.g., the y direction or the -y direction), and the first bridge portions 12 connect adjacent first island portions 11 to each other.

Each first island portion 11 may be connected to a plurality of first bridge portions 12. For example, each first island portion 11 may be connected to four first bridge portions 12. Two first bridge portions 12 may be respectively arranged on two opposite sides of the first island portion 11 in the first direction (e.g., the x direction or the -x direction), and the remaining two first bridge portions 12 may be respectively arranged on two opposite sides of the first island portion 11 in the second direction (e.g., the y direction or the -y direction). According to an embodiment, four first bridge portions 12 may be respectively connected to four sides of the first island portion 11. The four first bridge portions 12 may be adjacent to corners of the first island portion 11, respectively.

The first bridge portions 12 may be spaced apart from each other by a first opening CS1 located between the first bridge portions 12. According to an embodiment, first openings CS1 each having an approximate H shape and first openings CS1 each having an approximate I shape, which is rotated by 90 degrees from the H shape,may be repeatedly and alternately arranged in the first direction (e.g., the x direction or the -x direction) and the second direction (e.g., the y direction or the -y direction). Two opposite ends of each first bridge portion 12 may be connected to two adjacent first island portions 11, respectively, where one side of each first bridge portion 12 may be spaced apart from one side of an adjacent first island portion 11 and/or one side of another first island portion 11 by the first opening CS1.

In a non-display area, for example, the first non-display area NDA1 shown in FIG. 4A, the display apparatus 1 may include second island portions 21 apart from each other and second bridge portions 22 connecting adjacent second island portions 21 to each other.

Each second island portion 21 may extend in the first direction (e.g., the x direction or the -x direction). The second island portions 21 may be apart from each other in the second direction (e.g., the y direction or the -y direction) intersecting the first direction (e.g., the x direction or the -x direction). Each second island portion 21 may include drivers of the gate driving circuit GDC (see FIG. 3) described above with reference to FIG. 3.

The second bridge portion 22 may have a serpentine shape. A length of the second bridge portion 22 may be greater than a shortest distance between adjacent second island portions 21 in the second direction (e.g., the y direction or the -y direction). According to an embodiment, the second bridge portion 22 may have an approximate omega Ω shape that is convex in the first direction (e.g., the x direction or the -x direction). The second bridge portions 22 may be arranged between adjacent second island portions 21 and may be apart from each other.

The second bridge portions 22 between adjacent second island portions 21 may be apart from each other by second openings CS2. Between adjacent second island portions 21, the second openings CS2 and the second bridge portions 22 may be alternately arranged in the first direction (e.g., the x direction or the -x direction). The second openings CS2 may have the same shapes. Two opposite ends of each second bridge portion 22 may be connected to two adjacent second island portions 21, respectively, where one side of each second bridge portion 22 may be apart from one side of an adjacent second island portion 21 and/or one side of another second island portion 22 by the second opening CS2.

One second island portion 21 disposed in the first non-display area NDA1 may correspond to the first island portions 11 in a plurality of rows arranged in the display area DA. For example, the one second island portion 21 disposed in the first non-display area NDA1 may correspond to first island portions 11 arranged in an i-th row in the display area DA and first island portions 11 arranged in an (i+1)th row in the display area DA (here, i is a positive number greater than 0). Although it is shown in FIG. 4A that one second island portion 21 corresponds to two rows of the first island portions 11, the disclosure is not limited thereto. According to another embodiment, one second island portion 21 arranged in the first non-display area NDA1 may correspond to n rows of the first island portions 11 arranged in the display area DA (here, n is a positive number equal to or greater than 3).

The non-display area, for example, the first non-display area NDA1, may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be arranged in the second sub-non-display area SNDA2, where the third bridge portions 23 connect the display area DA to the first sub-non-display area SNDA1. One end of each third bridge portion 23 may be connected to the second island portion 21 and/or the second bridge portion 22, and the other end of the third bridge portion 23 may be connected to the first island portion 11 and/or the first bridge portion 12.

Each of the third bridge portions 23 may have a serpentine shape. According to an embodiment, the shape of the third bridge portion 23 may be different from the shape of each of the first bridge portion 12 and the second bridge portion 22. According to an embodiment, as shown in FIG. 4A, the third bridge portion 23 may have an approximate omega Ω shape that is convex in the second direction (e.g., the y direction or the -y direction). The third bridge portions 23 may have symmetrical structures, that is, one of adjacent third bridge portions 23 arranged in the second direction (for example, the y direction or the -y direction) may be convex in the y direction and the other may be convex in the -y direction. A structure in which third openings CS3 and fourth openings CS4 of different shapes are repeated may be provided between the third bridge portions 23. A width of the third bridge portion 23 may be different from a width of the first bridge portion 12 and a width of the second bridge portion 22. According to an embodiment, the width of the third bridge portion 23 may be greater than the width of the first bridge portion 12 and may be less than the width of the second bridge portion 22.

It is shown in FIG. 4A that the second island portion 21 and the second bridge portion 22 in the first non-display area NDA1 have different shapes from the shapes of the first island portion 11 and the first bridge portion 12 in the display area DA, respectively. According to another embodiment, the second island portion 21 and the second bridge portion 22 in the non-display area may have the same shapes as the first island portion 11 and the first bridge portion 12 in the display area DA, respectively.

FIG. 4B is an enlarged plan view of a region IV of FIG. 3, which is a portion of the display apparatus 1 according to an embodiment of the disclosure.

Referring to FIG. 4B, the display apparatus 1 includes the first island portions 11 apart from each other, and the first bridge portions 12 in the display area DA, where the first bridge portions 12 are apart from each other by the first opening CS1 and connect adjacent first island portions 11 to each other. The structure of the display area DA in FIG. 4B may be the same as the structure of the display area DA described above with reference to FIG. 4A.

The display apparatus 1 may include second island portions 21 and second bridge portions 22 arranged in a non-display area, for example, the first non-display area NDA1. According to an embodiment, the second island portions 21 and the second bridge portions 22 may have substantially the same shapes as the first island portions 11 and the first bridge portions 12, respectively.

The second island portions 21 may be apart from each other in the first direction (e.g., the x direction or the -x direction) and the second direction (for example, the y direction or the -y direction) in the non-display area, for example, the first non-display area NDA1. Each of the second bridge portions 22 may connect adjacent second island portions 21 to each other. The second bridge portions 22 may be spaced apart from each other by a second opening CS2 located between the second bridge portions 22.

The second opening CS2 may have substantially the same shape as the first opening CS1. For example, the second opening CS2 having an approximate H shape and the second opening CS2 having an approximate I shape may be alternately and repeatedly arranged in the non-display area, for example, the first non-display area NDA1. Two opposite ends of each second bridge portion 22 may be connected to two adjacent second island portions 21, respectively, where one side of each second bridge portion 2 may be apart from one side of an adjacent second island portion 21 and/or one side of another second island portion 22 by the second opening CS2.

Each second island portion 21 may be connected to four second bridge portions 22. Each second island portion 21 may include drivers of the gate driving circuit GDC (see FIG. 2) described above with reference to FIG. 3.

The second island portions 21 in one row arranged in the first non-display area NDA1 may correspond to the first island portions 11 in one of row arranged in the display area DA. For example, the second island portions 21 arranged in the i-th row in the first direction (e.g., the x direction or the -x direction) in the first non-display area NDA1 may correspond to the first island portions 11 arranged in the same row, for example, in the i-th row, in the display area DA (here, i is a positive number greater than 0).

The display apparatus 1 may include third bridge portions 23 arranged in a second sub-non-display area SNDA2, where the third bridge portions 23 connect the display area DA to the first sub-non-display area SNDA1. The non-display area, for example, the first non-display area NDA1, may include a first sub-non-display area SNDA1 in which the second island portions 21 and the second bridge portions 22 are arranged, and a second sub-non-display area SNDA2 including the third bridge portions 23 and located between the first sub-non-display area SNDA1 and the display area DA. Each third bridge portion 23 may be substantially the same as each first bridge portion 12 and each second bridge portion 22. For example, a width of the third bridge portion 23 may be the same as a width of the first bridge portion 12 and a width of the second bridge portion 22.

FIG. 4C is an enlarged plan view of a region IV of FIG. 3, which is a portion of the display apparatus according to an embodiment of the disclosure.

Referring to FIG. 4C, the display apparatus 1 may include first island portions 11 and first bridge portions 12 in the display area DA, where the first island portions 11 are apart from each other in the first direction (e.g., the x direction or the -x direction) and the second direction (e.g., the y direction or the -y direction), and the first bridge portions 12 connect adjacent first island portions 11 to each other.

The first bridge portions 12 may be arranged apart from each other by a first opening CS1 located between the first bridge portions 12. Each of the first bridge portions 12 may have a serpentine shape. For example, as shown in FIG. 4C, the first bridge portion 12 may have a shape of a roughly 'alphabet S', like a shape including two round portions 12R and a straight portion 12S between the two round portions 12R.

Each first island portion 11 may be connected to a plurality of first bridge portions 12. For example, each first island portion 11 may be connected to four first bridge portions 12. Two first bridge portions 12 may be respectively arranged on two opposite sides of the first island portion 11 in the first direction (e.g., the x direction or the -x direction), and the remaining two first bridge portions 12 may be respectively arranged on two opposite sides of the first island portion 11 in the second direction (e.g., the y direction or the -y direction). Four first bridge portions 12 may be respectively connected to four sides of the first island portion 11. The four first bridge portions 12 may be adjacent to corners of the first island portion 11, respectively.

The display apparatus 1 may include second island portions 21 and second bridge portions 22 in the non-display area, for example, in the first non-display area NDA1 shown in FIG. 4C, where the peripheral island portions 21 are apart from each other in the first direction (e.g., the x direction or the -x direction) and the second direction (e.g., the y direction or the -y direction) and the second bridge portions 22 connect adjacent second island portions 21 to each other.

The second bridge portions 22 may be arranged apart from each other by a second opening CS2 located between the second bridge portions 22. Each of the second bridge portions 22 may have a serpentine shape. For example, as shown in FIG. 4C, the second bridge portion 22 may have an approximately 'alphabet S' shape. A size and/or a width of the second bridge portion 22 may be different from a size and/or a width of the first bridge portion 12. For example, the size and/or a width of the second bridge portion 22 may be greater than the size and/or the width of the first bridge portion 12. A curvature radius of a round portion of the second bridge portion 22 may be different from a curvature radius of a round portion of the first bridge portion 12. For example, the curvature radius of the round portion of the second bridge portion 22 may be greater than the curvature radius of the round portion of the first bridge portion 12.

Each second island portion 21 may be connected to a plurality of second bridge portions 22. Each second island portion 21 may be connected to four second bridge portions 22. Two second bridge portions 22 may be respectively arranged on two opposite sides of the second island portion 21 in the first direction (e.g., the x direction or the -x direction), and the remaining two second bridge portions 22 may be respectively arranged on two opposite sides of the second island portion 21 in the second direction (e.g., the y direction or the -y direction). According to an embodiment, four second bridge portions 22 may be respectively connected to four sides of the second island portion 21. Each second bridge portion 22 may be connected to a central portion of each side of the second island portion 21.

The second island portions 21 in one row arranged in the first non-display area NDA1 may correspond to the first island portions 11 in a plurality of rows arranged in the display area DA. For example, the second island portions 21 in one row arranged in the first non-display area NDA1 may correspond to the first island portions 11 in an i-th row and the first island portions 11 in an (i+1)th row in the display area DA (here, i is a positive number greater than 0). According to another embodiment, the second island portions 21 in one row may correspond to n rows of the first island portions 11 (here, n is a positive number equal to or greater than 3).

The non-display area, for example, the first non-display area NDA1, may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be arranged in the second sub-non-display area SNDA2, where the third bridge portions 23 connect the display area DA to the first sub-non-display area SNDA1. One end of each third bridge portion 23 may be connected to the second island portion 21, and the other end of the third bridge portion 23 may be connected to the first island portion 11. For example, one end of the third bridge portion 23 may be connected to the central portion of one side of the second island portion 21, and the other end of the third bridge portion 23 may be connected to the central portion of one side of the first island portion 11.

Each of the third bridge portions 23 may have a serpentine shape. According to an embodiment, the shape of the third bridge portion 23 may be different from the shape of each of the first bridge portion 12 and the second bridge portion 22. A width of the third bridge portion 23 may be different from a width of the first bridge portion 12 and a width of the second bridge portion 22. The width of the third bridge portion 23 may be greater than the width of the first bridge portion 12 and may be less than the width of the second bridge portion 22. In the second direction (e.g., the y direction or the -y direction), third openings CS3 and fourth openings CS4 having different shapes may be alternately arranged between the third bridge portions 23.

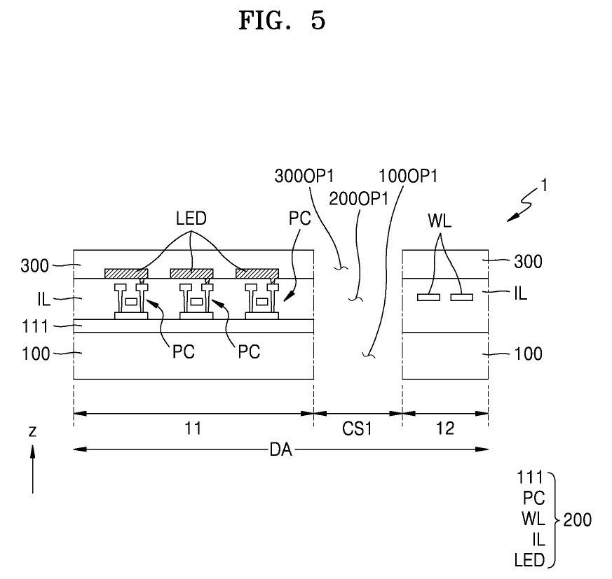

FIG. 5 is a schematic cross-sectional view of the first island portion 11 and the first bridge portion 12 arranged in the display area DA of the display apparatus 1 according to an embodiment of the disclosure.

Referring to FIG. 5, the first island portion 11 and the first bridge portion 12 arranged in the display area DA may be apart from each other with the first opening CS1 therebetween. The first island portion 11 may include light-emitting elements LED and circuits, for example, pixel driving circuit portions PC, electrically connected to the light-emitting elements LED and configured to drive the light-emitting elements. The first bridge portion 12 may include connection wiring WL electrically connected to the pixel driving circuit portions PC respectively arranged on adjacent first island portions 11.

Regarding the first island portion 11, a buffer layer 111 including an inorganic insulating material may be disposed on a substrate 100, and the pixel driving circuit portion PC may be disposed on the buffer layer 111. An insulating layer IL including an inorganic insulating material and/or an organic insulating material may be disposed between the pixel driving circuit portions PC and the light-emitting elements LED. The light-emitting elements LED may be disposed on the insulating layer IL and electrically connected to the pixel driving circuit portions PC corresponding to the light-emitting elements LED. The light-emitting elements LED may be configured to emit light of different colors or emit light of the same color. According to an embodiment, the light-emitting elements LED may be configured to respectively emit red light, green light, and blue light. According to some embodiments, the light-emitting elements LED may be configured to emit white light. According to another embodiment, the light-emitting elements LED may be configured to respectively emit red light, green light, blue light, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate, for example. According to an embodiment, the substrate 100 may be a single layer including the above-described polymer resin. According to another embodiment, the substrate 100 may have a multi-layered structure including a base layer including the aforementioned polymer resin and a barrier layer including an inorganic insulating material. The substrate 100 including polymer resin may be flexible, rollable, or bendable.

According to an embodiment, it is shown in FIG. 5 that three pixel driving circuit portions PC are arranged in the first island portion 11 and three light-emitting elements LED are respectively connected to the three pixel driving circuit portions PC, but the disclosure is not limited thereto. According to another embodiment, the respective numbers of pixel driving circuit portions PC and light-emitting elements LED arranged in the first island portion 11 may be one, two, four, or more.

An encapsulation layer 300 may be disposed on the light-emitting elements LED, and may protect the light-emitting elements LED from an external force and/or moisture transmission. The encapsulation layer 300 may include an organic encapsulation layer and/or an inorganic encapsulation layer. According to some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked in the thickness direction (i.e., z direction) of the display apparatus 1. According to another embodiment, the encapsulation layer 300 may include an organic material such as resin. According to some embodiments, the encapsulation layer 300 may include urethane epoxy acrylate. The encapsulation layer 300 may include a photosensitive material, for example, a photoresist.

Regarding the first bridge portion 12, the insulating layer IL including an organic insulating material may be disposed on the substrate 100. Unlike the first island portion 11, the first bridge portion 12, which is relatively transformed much when the display apparatus 1 is stretched, may not include a layer including an inorganic insulating material that is prone to cracking.

According to an embodiment, the substrate 100 corresponding to the first bridge portion 12 may have the same stack structure as the substrate 100 corresponding to the first island portion 11. According to an embodiment, the substrate 100 corresponding to the first bridge portion 12 and the substrate 100 corresponding to the first island portion 11 may be polymer resin layers simultaneously formed during the same process. According to another embodiment, the substrate 100 corresponding to the first bridge portion 12 may have a different stack structure from the substrate 100 corresponding to the first island portion 11. According to some embodiments, the substrate 100 corresponding to the first bridge portion 12 may have a multi-layered structure including a base layer including polymer resin and a barrier layer including an inorganic insulating material, and the substrate 100 corresponding to the first bridge portion 12 may have a structure of a polymer resin layer without a layer including an inorganic insulating material.

As described above, the connection wirings WL of the first bridge portion 12 may be signal lines (e.g., a gate line and a data line) configured to provide electrical signals to transistors included in the pixel driving circuit portions PC of the first island portion 11, or may be voltage lines (e.g., a driving voltage line and an initialization voltage line) configured to provide voltages. The encapsulation layer 300 may also be disposed in the first bridge portion 12. According to another embodiment, the encapsulation layer 300 may not be present in the first bridge portion 12.

Referring to FIGS. 4A through 4C and FIG. 5, the substrate 100 corresponding to the first island portion 11 and the substrate 100 corresponding to the first bridge portion 12 may be connected to each other. In other words, the plan views of FIGS. 4A through 4C may be substantially the same as the plan view of the substrate 100 of FIG. 5. In other words, the substrate 100 may include a region corresponding to the first island portion 11, a region corresponding to the first bridge portion 12, and an opening 100OP1 having the same shape as the shape of the first opening CS1.

Similarly, the encapsulation layer 300 corresponding to the first island portion 11 and the encapsulation layer 300 corresponding to the first bridge portion 12 may be connected to each other. For example, the plan views of FIGS. 4A through 4C may be substantially the same as the plan view of the encapsulation layer 300. In other words, the encapsulation layer 300 may include a region corresponding to the first island portion 11, a region corresponding to the first bridge portion 12, and an opening 300OP1 having the same shape as the shape of the first opening CS1.

A circuit-light-emitting element layer 200 between the substrate 100 and the encapsulation layer 300 may include the buffer layer 111, the pixel driving circuit portions PC, the connection wiring WL, the insulating layer IL, and the light-emitting elements LED. Similar to the substrate 100, the plan views of FIGS. 4A through 4C may be substantially the same as the plan view of the circuit-light-emitting element layer 200. In other words, the circuit-light-emitting element layer 200 may include an opening 200OP1 having the same shape as the first opening CS1.

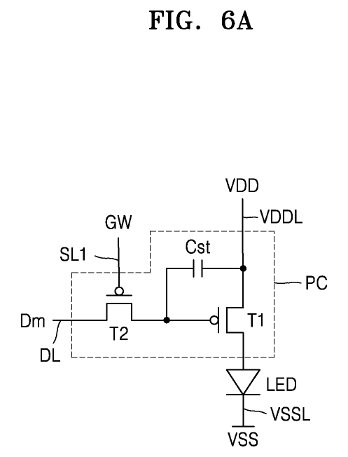

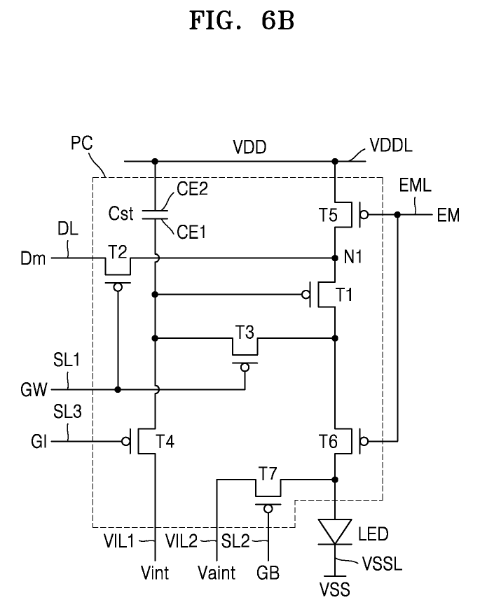

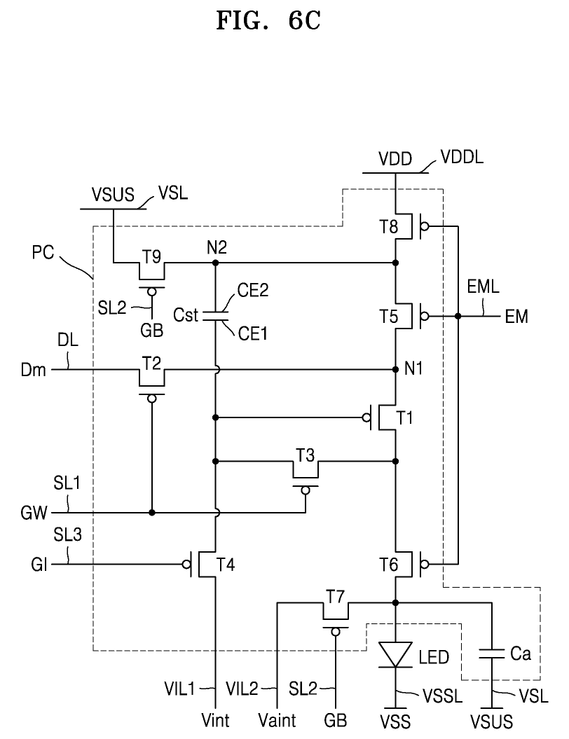

FIGS. 6A through 6C are equivalent circuit diagrams of a subpixel of the display apparatus 1 according to an embodiment of the disclosure.

Referring to FIG. 6A, a light-emitting element LED corresponding to the subpixel may be electrically connected to a pixel driving circuit portion PC, and the pixel driving circuit portion PC may include a first transistor T1, a second transistor T2, and a storage capacitor Cst. The pixel driving circuit portion PC may be electrically connected to signal lines and voltage lines. The signal lines may include a gate line such as a first scan line SL1, and a data line DL, and the voltage lines may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transfer a data signal Dm input from the data line DL to the first transistor T1 according to the first scan signal GW input from the first scan line SL1.

The storage capacitor Cst may be electrically connected to the second transistor T2 and the first voltage line VDDL, and may store a voltage corresponding to a difference between a voltage received from the second transistor T2 and the first power supply voltage VDD supplied by the first voltage line VDDL.

The first transistor T1, which is a driving transistor, may be configured to control a driving current flowing through the light-emitting element LED. The first transistor T1 may be connected to the first voltage line VDDL and the storage capacitor Cst. The first transistor T1 may control a driving current flowing from the first voltage line VDDL to the light-emitting element LED according to a voltage value stored in the storage capacitor Cst. The light-emitting element LED may emit light having a certain brightness due to the driving current. A first electrode of the light-emitting element LED may be electrically connected to the first transistor T1, and a second electrode of the light-emitting element LED may be electrically connected to a second voltage line VSSL configured to supply a second power supply voltage VSS.

In FIG. 6A, the pixel driving circuit portion PC includes two transistors and one storage capacitor. However, according to another embodiment, the pixel driving circuit portion PC may include three or more transistors.

Referring to FIG. 6B, the pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC is electrically connected to signal lines and voltage lines. The signal lines may include gate lines, such as a first scan line SL1, a second scan line SL2, a third scan line SL3, and a light-emission control line EML, and a data line DL. The voltage lines may include first and second initializing voltage lines VIL1 and VIL2 and the first voltage line VDDL.

The first voltage line VDDL may transmit the first power supply voltage VDD to the first transistor T1. The first initializing voltage line VIL1 may transmit, to the pixel driving circuit portion PC, a first initializing voltage Vint that initializes the first transistor T1. The second initializing voltage line VIL2 may transmit, to the pixel driving circuit portion PC, a second initializing voltage Vaint that initializes a first electrode of the light-emitting element LED.

The first transistor T1 may be electrically connected to the first voltage line VDDL through the fifth transistor T5, and may be electrically connected to the light-emitting element LED through the sixth transistor T6. The first transistor T1 serves as a driving transistor, and receives a data signal Dm according to a switching operation of the second transistor T2 and supplies a driving current to the light-emitting element LED.

The second transistor T2, which is a data write transistor, is electrically connected to the first scan line SL1 and the data line DL. The second transistor T2 is electrically connected to the first voltage line VDDL through the fifth transistor T5. The second transistor T2 is turned on in response to a first scan signal GW received through the first scan line SL1, to perform a switching operation of transmitting the data signal Dm received through the data line DL to a first node N1.

The third transistor T3 is electrically connected to the first scan line SL1, and is electrically connected to the light-emitting element LED via the sixth transistor T6. The third transistor T3 may be turned on according to the first scan signal SL1 received via the first scan line SL1, and may diode-connect the first transistor T1.

The fourth transistor T4, which is a first initialization transistor, is electrically connected to the third scan line SL3 and the first initializing voltage line VIL1. The fourth transistor T4 is turned on in response to a third scan signal GI received through the second scan line SL3, and transmit the first initializing voltage Vint from the first initializing voltage line VIL1 to the gate electrode of the first transistor T1 to thereby initialize the voltage of the gate electrode of the first transistor T1. The third scan signal GI may correspond to a first scan signal of another pixel driving circuit portion arranged in a row previous to the row of the current pixel driving circuit portion PC.

The fifth transistor T5 may be an operation control transistor, and the sixth transistor T6 may be a light-emission control transistor. The fifth transistor T5 and the sixth transistor T6 are electrically connected to the light-emission control line EML, and are simultaneously turned on according to a light-emission control signal EM received through the light-emission control line EML and form a current path so that the driving current flows from the first voltage line VDDL toward the light-emitting element LED.

The seventh transistor T7, which is a second initialization transistor, may be electrically connected to the second scan line SL2, the second initializing voltage line VIL2, and the sixth transistor T6. The seventh transistor T7 may be turned on according to a second scan signal GB received through the second scan line SL2, and may be configured to transfer the second initializing voltage Vaint from the second initializing voltage line VIL2 to the first electrode of the light-emitting element LED to thereby initialize the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between the voltage of the first voltage line VDDL and the voltage of the gate electrode of the first transistor T1.

Referring to FIG. 6C, the pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit portion PC is electrically connected to signal lines and voltage lines. The signal lines may include gate lines, such as a first scan line SL1, a second scan line SL2, a third scan line SL3, and a light-emission control line EML, and a data line DL. The voltage lines may include first and second initializing voltage lines VIL1 and VIL2, a sustain voltage line VSL, and the first voltage line VDDL.

The first voltage line VDDL may transmit the first power supply voltage VDD to the first transistor T1. The first initializing voltage line VIL1 may transmit, to the pixel driving circuit portion PC, a first initializing voltage Vint that initializes the first transistor T1. The second initializing voltage line VIL2 may transmit, to the pixel driving circuit portion PC, a second initializing voltage Vaint that initializes a first electrode of the light-emitting element LED. The sustain voltage line VSL may be configured to provide a sustain voltage VSUS to a second node N2, for example, to the second electrode CE2 of the storage capacitor Cst, during an initialization section and a data-write section.

The first transistor T1 may be electrically connected to the first voltage line VDDL through the fifth transistor T5 and the eighth transistor T8, and may be electrically connected to the light-emitting element LED through the sixth transistor T6. The first transistor T1 serves as a driving transistor, and may receive a data signal Dm according to a switching operation of the second transistor T2 and supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to a scan signal GW received through the scan signal line GWL, to perform a switching operation of transmitting the data signal Dm received through the data line DL to a first node N1.

The third transistor T3 is electrically connected to the first scan line SL1, and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initializing voltage line VIL1, and is turned on according to a third scan signal GI received via the third scan line SL3 and transmit the first initializing voltage Vint from the first initializing voltage line VIL1 to the gate electrode of the first transistor T1 to thereby initialize the voltage of the gate electrode of the first transistor T1. The third scan signal GI may correspond to a first scan signal of another pixel driving circuit portion arranged in a row previous to the row of the current pixel driving circuit portion PC.

The fifth transistor T5, the sixth transistor T6, and the eighth transistor T8 are electrically connected to the light-emission control line EML, and are simultaneously turned on according to a light-emission control signal EM received through the light-emission control line EML and form a current path so that the driving current flows from the first voltage line VDDL toward the light-emitting element LED.

The seventh transistor T7, which is a second initialization transistor, may be electrically connected to the second scan line SL2, the second initializing voltage line VIL2, and the sixth transistor T6. The seventh transistor T7 is turned on according to a bypass control signal GB received through the bypass control line GBL, and is configured to transfer the second initializing voltage Vaint from the second initializing voltage line VIL2 to the first electrode of the light-emitting element LED to thereby initialize the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on according to the second scan signal GB transferred through the second scan line SL2, and may be configured to transfer the sustain voltage VSUS to the second node N2, for example, the second electrode CE2 of the storage capacitor Cst, during the initialization section and the data-write section.

Each of the eighth transistor T8 and the ninth transistor T9 may be electrically connected to the second node N2, for example, the second electrode CE2 of the storage capacitor Cst. According to some embodiments, during the initialization section and the data-write section, the eighth transistor T8 may be turned off and the ninth transistor T9 may be turned on, and, during an emission section, the eighth transistor T8 may be turned on and the ninth transistor T9 may be turned off. Because, during the initialization section and the data-write section, the sustain voltage VSUS is transferred to the second node N2, uniformity in brightness of the display apparatus (e.g., long range uniformity (LRU)) according to a voltage drop of the first voltage line VDDL may be improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. While the seventh transistor T7 and the ninth transistor T9 are being turned on, the auxiliary capacitor Ca stores and maintains a voltage corresponding to a difference between the voltage of the first electrode of the light-emitting element LED and the voltage of the sustain voltage line VSL, thereby preventing a black brightness from rising when the sixth transistor T6 is turned off.

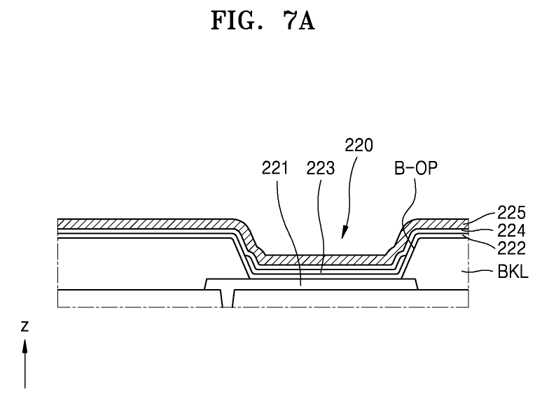

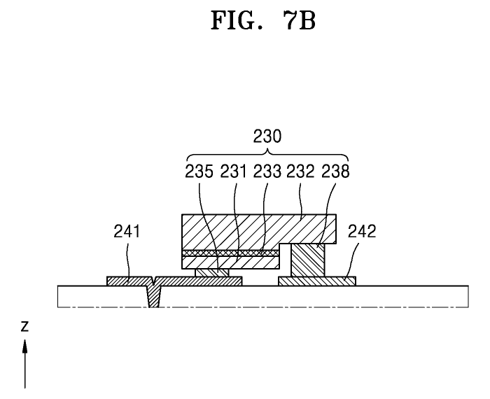

FIG. 7A is a schematic cross-sectional view of a light-emitting element of a display apparatus according to an embodiment of the disclosure.

Referring to FIG. 7A, the light-emitting element according to an embodiment of the disclosure may include an organic light-emitting diode 220 including an organic material. The organic light-emitting diode 220 may include a first electrode 221 disposed on an insulating layer, a second electrode 225 facing the first electrode 221, and an emission layer 223 interposed between the first electrode 221 and the second electrode 225. A first functional layer 222 may be interposed between the first electrode 221 and the emission layer 223, and a second functional layer 224 may be interposed between the emission layer 223 and the second electrode 225.

An edge of the first electrode 221 may be covered with a bank layer BKL including an insulating material. The bank layer BKL may include an opening B-OP overlapping a center portion of the first electrode 221.

The first electrode 221 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first electrode 221 may include a reflective layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to another embodiment, the first electrode 221 may further include a layer formed of ITO, IZO, ZnO, or In₂O₃ above/below the reflective layer.

The emission layer 223 may include a high molecular or low molecular organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the second electrode 225 may further include a layer, such as ITO, IZO, ZnO, or In₂O₃, on the (semi)transparent layer including any of the above-described materials.

FIG. 7B is a schematic cross-sectional view of a light-emitting element of a display apparatus according to an embodiment of the disclosure.

Referring to FIG. 7B, the light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, disposed on the same layer.

According to some embodiments, the first semiconductor layer 231 may include a p-type semiconductor layer. The p-type semiconductor layer may be selected from semiconductor materials having a composition formula of InxAlyGa1-x-yN (0≤x≤1, 0≤y≤1, 0≤x+y≤1), for example, GaN, AlN, AlGaN, InGaN, InN, InAlGaN, and AlInN, and may be doped with a p-type dopant such as Mg, Zn, Ca, Sr, or Ba.

The second semiconductor layer 232 may include, for example, an n-type semiconductor layer. The n-type semiconductor layer may be selected from semiconductor materials having a composition formula of InxAlyGa1-x-yN (0≤x≤1, 0≤y≤1, 0≤x+y≤1), for example, GaN, AlN, AlGaN, InGaN, InN, InAlGaN, and AlInN, and may be doped with an n-type dopant such as Si, Ge, or Sn.

The intermediate layer 233, in which electrons and holes are recombined, may transit to a low energy level due to recombination between electrons and holes, and may generate light having a wavelength corresponding to the low energy level. The intermediate layer 233 may be formed by including a semiconductor material having a composition formula of InxAlyGa1-x-yN (0≤x≤1, 0≤y≤1, 0≤x+y≤1), and may have a single quantum well structure or a multi-quantum well (MQW) structure. Alternatively, the intermediate layer 233 may have a quantum wire structure or a quantum dot structure.

It has been described with reference to FIG. 7B that the first semiconductor layer 231 includes a p-type semiconductor layer and the second semiconductor layer 232 includes an n-type semiconductor layer, but the disclosure is not limited thereto. According to another embodiment, the first semiconductor layer 231 may include an n-type semiconductor layer, and the second semiconductor layer 232 may include a p-type semiconductor layer.

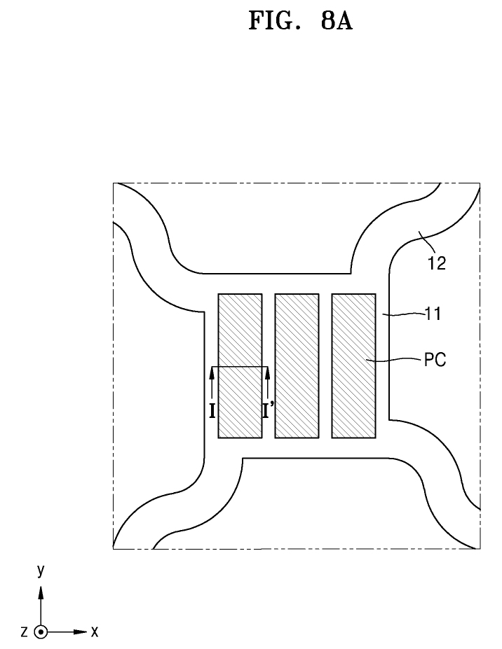

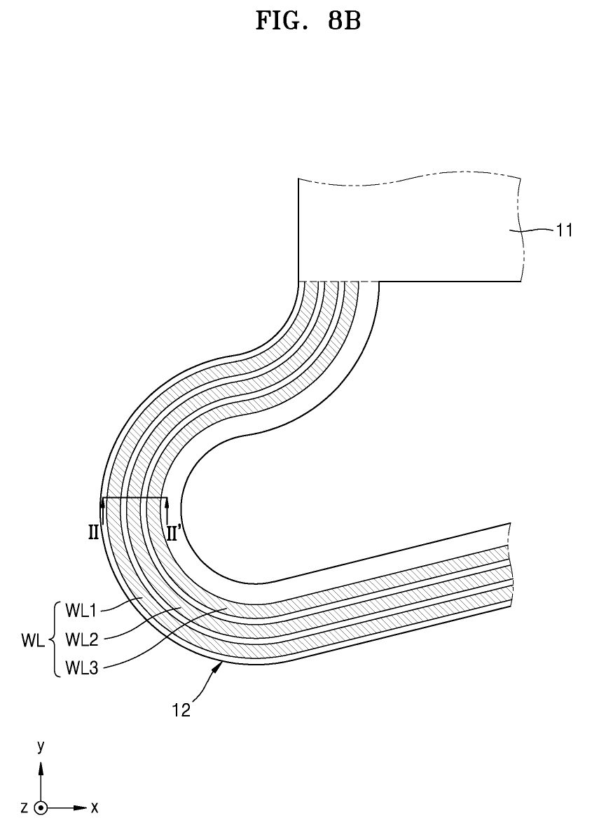

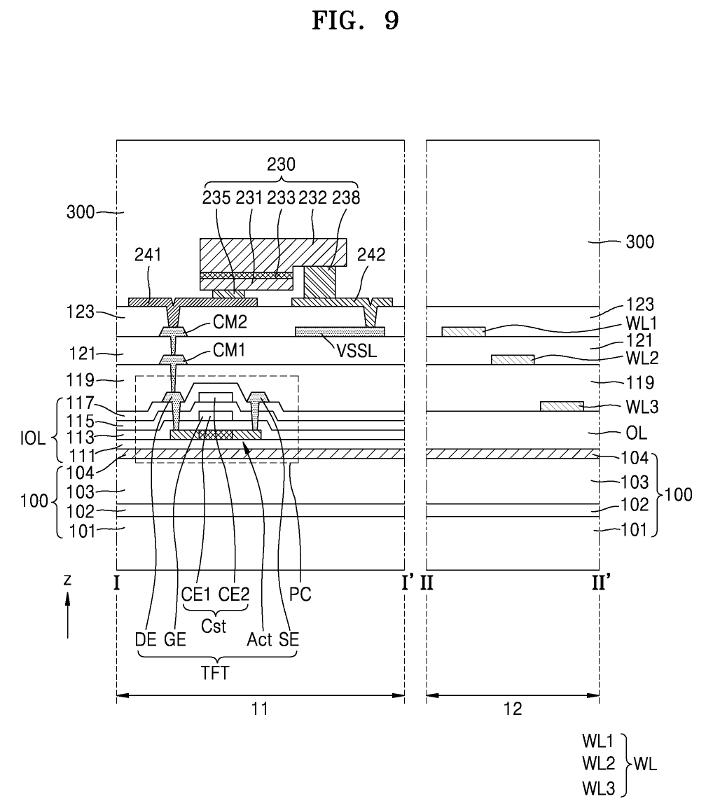

FIG. 8A is an enlarged plan view of a first island portion of a display apparatus according to an embodiment of the disclosure, and FIG. 8B is a plan view showing an arrangement of wiring on a first bridge portion of a display apparatus according to an embodiment of the disclosure. FIG. 9 shows a cross-section taken along line I-I' of FIG. 8A and a cross-section taken along line II-II' of FIG. 8B.

Referring to FIG. 8A, the first island portion 11 disposed in the display area DA may include a light-emitting element and a pixel driving circuit portion PC electrically connected thereto. As described above, the pixel driving circuit portion PC may include transistors and at least one capacitor. Although three pixel driving circuit portions PC are arranged in the first island portion 11 in FIG. 8A, the disclosure is not limited thereto. According to another embodiment, the respective numbers of pixel driving circuit portions PC and light-emitting elements arranged in the first island portion 11 may be one, two, four, or more.

Referring to FIG. 9, the substrate 100 corresponding to the first island portion 11 may include a first base layer 101, a first sub-barrier layer 102, a second base layer 103, and a second sub-barrier layer 104. Each of the first base layer 101 and the second base layer 103 may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate, for example. Each of the first sub-barrier layer 102 and the second sub-barrier layer 104 may include an inorganic insulating material such as silicon oxide, silicon nitride, or silicon oxynitride.

A buffer layer 111 may be disposed on the substrate 100, and the pixel driving circuit portion PC may be disposed on the buffer layer 111. The buffer layer 111 may include an inorganic insulating material such as silicon oxide, silicon nitride, or silicon oxynitride.

A thin-film transistor TFT may include a semiconductor layer Act, a gate electrode GE, a source electrode SE, and a drain electrode DE. In FIG. 9, the thin-film transistor TFT is a top gate type in which the gate electrode GE is arranged on the semiconductor layer Act with a gate insulating layer 113 therebetween. However, according to another embodiment, the thin-film transistor TFT may be a bottom gate type.

The semiconductor layer Act may include polysilicon. Alternatively, the semiconductor layer Act may include amorphous silicon, an oxide semiconductor, or an organic semiconductor. The gate electrode GE may include a low resistance metal material. The gate electrode GE may include a conductive material including molybdenum (Mo), aluminum (Al), copper (Cu), and titanium (Ti), and may be formed as a multi-layer or single layer including the aforementioned materials.

The gate insulating layer 113 between the semiconductor layer Act and the gate electrode GE may include an inorganic insulating material such as silicon oxide, silicon nitride, silicon oxynitride, aluminum oxide, or titanium oxide. The gate insulating layer 113 may be a single layer or multi-layer including the aforementioned materials.

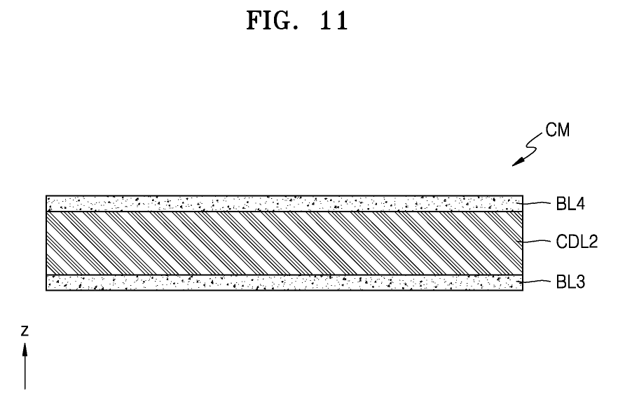

The source electrode SE and the drain electrode DE may be located on the same layer, for example, on a second interlayer-insulating layer 117, and may include the same materials. The source electrode SE and the drain electrode DE may include a conductive material, and may be formed as a multi-layer or single layer. The source electrode SE and the drain electrode DE will be described in detail later with reference to FIG. 11. The second interlayer-insulating layer 117 may include an inorganic insulating material such as silicon oxide, silicon nitride, silicon oxynitride, aluminum oxide, or titanium oxide, and may be a single layer or multiple layers including the aforementioned materials.

The storage capacitor Cst may include a first electrode CE1 and a second electrode CE2 overlapping each other with a first interlayer-insulating layer 115 therebetween. The storage capacitor Cst and the thin-film transistor TFT may overlap each other. With regard to this, FIG. 9 illustrates a case where the gate electrode GE of the thin-film transistor TFT is the first electrode CE1 of the storage capacitor Cst. According to another embodiment, the storage capacitor Cst and the thin-film transistor TFT may not overlap each other. The storage capacitor Cst may be covered by the second interlayer-insulating layer 117. The second electrode CE2 of the storage capacitor Cst may include a conductive material, and may be formed as a multi-layer or single layer. The first interlayer-insulating layer 115 may be disposed between the gate insulating layer 113 and the second interlayer-insulating layer 117. The first interlayer-insulating layer 115 may include an inorganic insulating material such as silicon oxide, silicon nitride, silicon oxynitride, aluminum oxide, or titanium oxide, and may be a single layer or multiple layers including the aforementioned materials.

An inorganic insulating material layer IOL on the substrate 100 may include, for example, the buffer layer 111, the gate insulating layer 113, the first interlayer-insulating layer 115, and the second interlayer-insulating layer 117.

A first organic insulating layer 119 may be disposed on the second interlayer-insulating layer 117, and a second organic insulating layer 121 may be disposed on the first organic insulating layer 119. Each of the first and second organic insulating layers 119 and 121 may include an organic insulating material such as polyimide.

A second voltage line VSSL may be disposed on the second organic insulating layer 121, and a third organic insulating layer 123 may be disposed on the second organic insulating layer 121 and the second voltage line VSSL. The third organic insulating layer 123 may include an organic insulating material such as polyimide. The second voltage line VSSL may include a conductive material, and may be formed as a multi-layer or single layer.

A first electrode pad 241 and a second electrode pad 242 may be arranged on the third organic insulating layer 123. The first electrode pad 241 may be electrically connected to the thin-film transistor TFT via a first connection electrode CM1 between the first organic insulating layer 119 and the second organic insulating layer 123 and a second connection electrode CM2 between the second organic insulating layer 121 and the third organic insulating layer 123. The first connection electrode CM1 and the second connection electrode CM2 will be described in detail later with reference to FIG. 11.

The inorganic light-emitting diode 230 on the first electrode pad 241 and the second electrode pad 242has been described above with reference to FIG. 7B. A light-emitting diode, for example, the inorganic light-emitting diode 230, may be protected by an encapsulating layer 300, and the encapsulating layer 300 may include an inorganic encapsulation layer and/or an organic encapsulation layer, or may include an organic material such as a resin. FIG. 9 illustrates that the light-emitting diode is the inorganic light-emitting diode 230 described above with reference to FIG. 7B. However, according to another embodiment, the light-emitting diode may be the organic light-emitting diode 220 described above with reference to FIG. 7A.

Referring to FIG. 8B, the first bridge portion 12 may include a plurality of connection wirings WL electrically connected to pixel driving circuit portions PC respectively arranged in adjacent first island portions 11. As described above, the connection wirings WL may be signal lines (e.g., a gate line and a data line) configured to provide electrical signals to transistors included in the pixel driving circuit portions PC of the first island portion 11, or may be voltage lines (e.g., a driving voltage line and an initialization voltage line) configured to provide voltages. FIG. 8B illustrates that a plurality of connection wirings WL, for example, first, second, and third connection wirings WL1, WL2, and WL3, are arranged on the first bridge portion 12, but the disclosure is not limited thereto. According to another embodiment, one connection wiring WL may be disposed on the first bridge portion 12.

Referring to FIG. 9, according to an embodiment, the substrate 100 corresponding to the first bridge portion 12 may have the same stack structure as the substrate 100 corresponding to the first island portion 11. According to an embodiment, the substrate 100 corresponding to the first bridge portion 12 may include a first base layer 101, a first sub-barrier layer 102, a second base layer 103, and a second sub-barrier layer 104. According to another embodiment, the substrate 100 corresponding to the first bridge portion 12 may have a different stack structure from the substrate 100 corresponding to the first island portion 11. The substrate 100 corresponding to the first bridge portion 12 may have a structure of the first base layer 101 and the second base layer 103.

The inorganic insulating layer IOL may not be disposed on the substrate 100, and an insulating layer OL, a first organic insulating layer 119, and a second organic insulating layer 121 may be arranged on the substrate 100. The insulating layer OL may include an organic insulating material such as polyimide. According to an embodiment, the insulating layer OL may have a thickness corresponding to the inorganic insulating layer IOL. According to some embodiments, the insulating layer OL may be omitted.

The plurality of connection wirings WL, for example, the first, second, and third connection wirings WL1, WL2, and WL3, may be arranged on different layers but electrically connected to the same pixel driver circuit portion PC. For example, the first connection wiring WL1 may be disposed between the second organic insulating layer 121 and the third organic insulating layer 123, the second connection wiring WL2 may be disposed between the first organic insulating layer 119 and the second organic insulating layer 121, and the third connection wiring WL3 may be disposed between the insulating layer OL and the first organic insulating layer 119. However, the disclosure is not limited thereto, and, according to another embodiment, at least some of the first, second, and third connection wirings WL1, WL2, and WL3 may be arranged on the same layer.

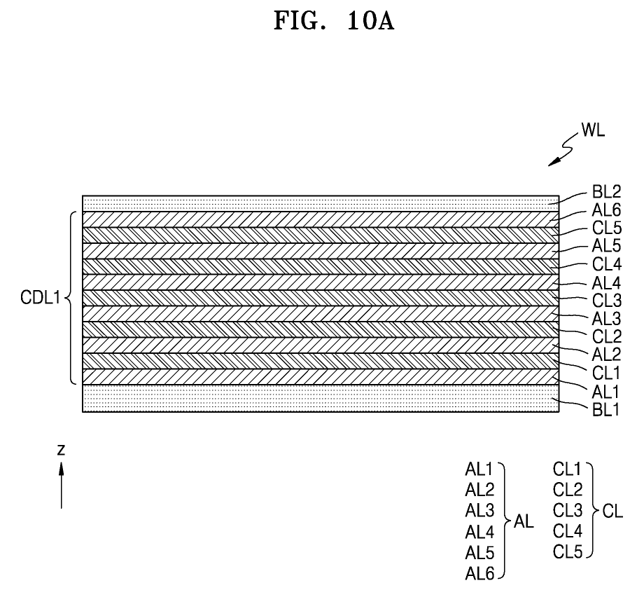

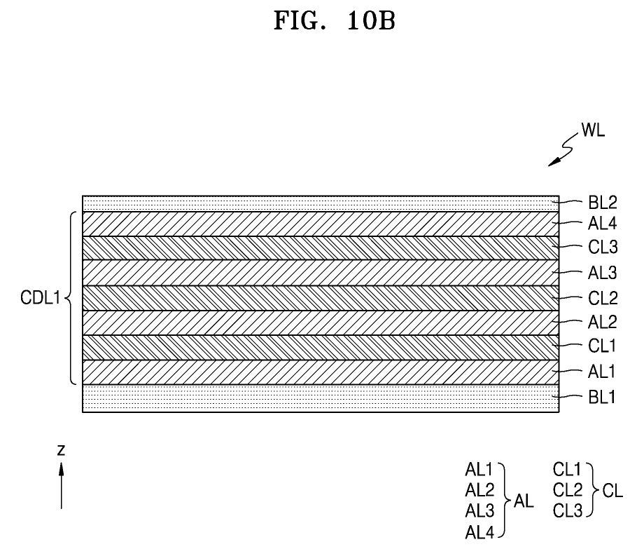

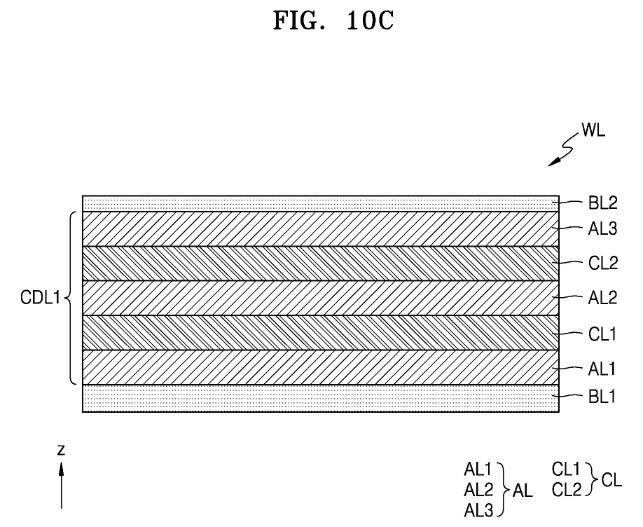

FIGS. 10A through 10C are cross-sectional views of a connection wiring of a display apparatus according to an embodiment of the disclosure.

Referring to FIGS. 10A, 10B, and 10C, the connection wiring WL disposed in the first bridge portion 12 (see FIG. 9) may have a triple-layer structure. The connection wiring WL may include a first barrier layer BL1, a first conductive layer CDL1 disposed on the first barrier layer BL1, and a second barrier layer BL2 disposed on the first conductive layer CDL1.

According to an embodiment, the connection wiring WL may have a stack structure in which the first conductive layer CDL1 includes a plurality of sublayers. The plurality of sublayers may include an amorphous sublayer AL (or a first sublayer) and a crystalline sublayer CL (or a second sublayer). The first conductive layer CDL1 may include a structure in which the amorphous sublayer AL and the crystalline sublayer CL are alternately stacked in the thickness direction (i.e., z direction) of the display apparatus 1.

According to an embodiment, the number of sublayers included in the first conductive layer CDL1 may be an odd number. For example, as shown in FIG. 10A, the first conductive layer CDL1 may include a total of eleven sublayers including six amorphous sublayers AL and five crystalline sublayers CL. Alternatively, as shown in FIG. 10B, the first conductive layer CDL1 may include a total of seven sublayers including four amorphous sublayers AL and three crystalline sublayers CL. Alternatively, as shown in FIG. 10C, the first conductive layer CDL1 may include a total of five sublayers including three amorphous sublayers AL and two crystalline sublayers CL.

According to an embodiment, amorphous sublayers AL may be arranged in a top portion and a bottom portion of the first conductive layer CDL1. Accordingly, the amorphous sublayer AL disposed in the bottom portion of the first conductive layer CDL1 may be in direct contact with the first barrier layer BL1, and the amorphous sublayer AL disposed in the top portion of the first conductive layer CDL1 may be in direct contact with the second barrier layer BL2.

For example, as shown in FIG. 10A, the first conductive layer CDL1 may have a structure in which a first amorphous sublayer AL1, a first crystalline sublayer CL1, a second amorphous sublayer AL2, a second crystalline sublayer CL2, a third amorphous sublayer AL3, a third crystalline sublayer CL3, a fourth amorphous sublayer AL4, a fourth crystalline sublayer CL4, a fifth amorphous sublayer AL5, a fifth crystalline sublayer CL5, a sixth amorphous sublayer AL6, a sixth crystalline sublayer CL6, and a seventh amorphous sublayer AL7 are sequentially stacked in the thickness direction (i.e., z direction) of the display apparatus 1. Alternatively, as shown in FIG. 10B, the first conductive layer CDL1 may have a structure in which a first amorphous sublayer AL1, a first crystalline sublayer CL1, a second amorphous sublayer AL2, a second crystalline sublayer CL2, a third amorphous sublayer AL3, a third crystalline sublayer CL3, and a fourth amorphous sublayer AL4 are sequentially stacked in the thickness direction (i.e., z direction) of the display apparatus 1. Alternatively, as shown in FIG. 10C, the first conductive layer CDL1 may have a structure in which a first amorphous sublayer AL1, a first crystalline sublayer CL1, a second amorphous sublayer AL2, a second crystalline sublayer CL2, and a third amorphous sublayer AL3 are sequentially stacked in the thickness direction (i.e., z direction) of the display apparatus 1.

The amorphous sublayer AL may be an alloy layer. The amorphous sublayer AL may include an alloy of aluminum and a rare-earth element. The amorphous sublayer AL may include an amorphous alloy, and the amorphous alloy may not include grain boundaries. The amorphous alloy may have a high elastic strain rate. Within an amorphous alloy, a fully amorphous alloy may undergo elastic deformation without plastic deformation. In this specification, the amorphous alloy may include a case in which the amorphous alloy is composed of fully amorphous phases, and a case in which nanocrystalline phases each having a crystallite size of only several nanometers exist in a distributed manner.

An atomic radius of a rare earth element may be greater than an atomic radius of aluminum. A ratio of a difference between the atomic radius of aluminum and the atomic radius of a rare earth element to the atomic radius of aluminum may be about 25% or more. When the atomic radius of a rare earth element differs by about 25% or more from the atomic radius of aluminum, atoms may be arranged in a regular manner, which may prevent crystallization. Electronegativity of a rare earth element may be less than electronegativity of aluminum. The electronegativity of a rare earth element may be about 1.0 to about 1.2. According to an embodiment, the rare earth element may include at least one of yttrium (Y), samarium (Sm), cerium (Ce), or lanthanum (La). This rare earth element may have an excellent glass forming ability.

According to an embodiment, the amorphous sublayer AL may include a binary alloy having a composition formula of AlaMb, where M may be at least one rare earth element selected from yttrium (Y), samarium (Sm), cerium (Ce), and lanthanum (La), a and b may represent the content (unit: atomic percent (at%)) of each element based on the total atomic amount of the amorphous sublayer AL, and a sum of a and b may be 100. According to an embodiment, a may be about 90 to about 96, and b may be about 4 to about 10. In other words, based on the total atomic amount of the amorphous sublayer AL, the content of aluminum (Al) may be about 90 at% to about 96 at%, and the content of the rare earth element M may be about 4 at% to about 10 at%. When the aluminum and the rare earth element (M) both included in the amorphous sublayer AL satisfy the above ranges, the amorphous sublayer AL may be an amorphous alloy layer having excellent resistivity. When the aluminum content is less than about 90 at%, resistivity of the amorphous sublayer AL may increase. When the content of the rare earth element M exceeds about 96 at%, the amorphous sublayer AL may not be formed as an amorphous alloy layer. When the content of the rare earth element M is less than about 4 at%, the amorphous sublayer AL may not be formed as an amorphous alloy layer. When the content of the rare earth element M exceeds about 10 at%, resistivity of the amorphous sublayer AL may increase. According to an embodiment, the amorphous sublayer AL may include an alloy having a composition formula of AlaYb (90≤a≤96, 4≤b≤10).

According to some embodiments, the amorphous sublayer AL may further include nickel and/or cobalt. Nickel and cobalt may be elements that stabilize amorphous phases. According to some embodiments, the amorphous sublayer AL may include a ternary alloy or a quaternary alloy. According to some embodiments, the amorphous sublayer AL may include a quaternary alloy having a composition formula of AlaMbNicCod, where M may be at least one rare earth element selected from yttrium (Y), samarium (Sm), cerium (Ce), and lanthanum (La), a, b, c, and d may represent the content (at%) of each element based on the total atomic amount of the amorphous sublayer AL, and a sum of a, b, c, and d may be 100. According to some embodiments, a may be about 80 to about 90, b may be about 5 to about 10, c may be about 3 to about 8, and d may be about 1 to about 3. In other words, based on the total atomic amount of the amorphous sublayer AL, the content of aluminum (Al) may be about 80 at% to about 90 at%, the content of the rare earth element M may be about 5 at% to about 10 at%, the content of nickel may be about 3 at% to about 8 at%, and the content of cobalt may be about 1 at% to about 3 at%. According to an embodiment, the amorphous sublayer AL may include an alloy having a composition formula of Al₈₅Y₈Ni₅Co₂.

The crystalline sublayer CL may include aluminum (Al). The crystalline sublayer CL may be a pure aluminum layer. The crystalline sublayer CL may be a crystalline aluminum layer. Pure aluminum undergoes plastic deformation after elastic deformation, and may have a relatively low elastic strain rate compared to amorphous alloys. For example, pure aluminum may have a low elastic strain rate of about 0.2% to about 0.5%. Pure aluminum may have a low resistivity of less than 10 microohm-centimeters (μΩ∙cm).

As described above, the amorphous sublayer AL and the crystalline sublayer CL may each include a material based on the same metal, for example, aluminum (Al). Because the first conductive layer CDL1 is formed by alternately arranging the amorphous sublayer AL and the crystalline sublayer CL as described above, the first conductive layer CDL1 may secure excellent electrical characteristics and also excellent stretchability.

Each of the first barrier layer BL1 and the second barrier layer BL2 may include an amorphous alloy. According to an embodiment, the first barrier layer BL1 and the second barrier layer BL2 may include a multi-component alloy composition of amorphous. The multi-component alloy composition of amorphous, which is an alloy including two or more different elements, may be defined as its phase being amorphous. The multi-component alloy composition may be a binary alloy composition containing two different elements, a ternary alloy composition containing three different elements, or a quaternary alloy composition containing four different elements.

As the first barrier layer BL1 and the second barrier layer BL2 include amorphous alloys, the connection wiring WL of a display apparatus according to an embodiment of the disclosure may suppress occurrence and propagation of cracks that may occur in the connection wiring WL. In detail, when the first barrier layer BL1 and the second barrier layer BL2 include crystalline metals and the display apparatus is stretched, crack embryos may occur at grain boundaries on respective surfaces of the first barrier layer BL1 and the second barrier layer BL2. The crack embryo may be referred to a localized defect structures at a beginning where cracks begin to be formed on a surface, as an initial stage of cracking. On the other hand, when the first barrier layer BL1 and the second barrier layer BL2 include amorphous alloys, crack origins to cause cracks have been removed from the respective surfaces of the first barrier layer BL1 and the second barrier layer BL2, so that, even when the display apparatus is stretched, formation of crack embryos may be suppressed.

That is, when the first barrier layer BL1 and the second barrier layer BL2 include amorphous alloys, an elastic strain limit of the connection wiring WL may be improved, and reliability of the display apparatus may be improved.

In this case, as Gibbs free energies (ΔG) of the amorphous alloys included in the first barrier layer BL1 and the second barrier layer BL2 decrease, this may suppress formation of crystal nuclei in the first barrier layer BL1 and the second barrier layer BL2, and may be advantageous for formation of an amorphous structure. That is, the lower a mixing enthalpy (ΔHmix) of the amorphous alloy is and the higher the mixing entropy (ΔSmix) of the amorphous alloy is, the better glass forming abilities (GFAs) of the first barrier layer BL1 and the second barrier layer BL2 may be. In other words, the lower the mixing enthalpies of the amorphous alloys included in the first barrier layer BL1 and the second barrier layer BL2 are, the more complex the composition of the amorphous alloy is, and the higher structural irregularity of the amorphous alloys is due to a difference in atomic size, the amorphous forming abilities (GFAs) of the first barrier layer BL1 and the second barrier layer BL2 may be improved, and the elastic strain rate of the connection wiring WL may also be increased.

To this end, the amorphous alloys included in the first barrier layer BL1 and the second barrier layer BL2 may include at least one of aluminum (Al), silicon (Si), titanium (Ti), cobalt (Co), nickel (Ni), copper (Cu), yttrium (Y), zirconium (Zr), or molybdenum (Mo). In detail, the first barrier layer BL1 and the second barrier layer BL2 may each include a multi-component alloy composition having one of titanium (Ti), molybdenum (Mo), zirconium (Zr), and aluminum (Al) as a main element.

According to an embodiment, the first barrier layer BL1 and the second barrier layer BL2 may each include a quaternary alloy composition having titanium (Ti) as a main element. For example, the first barrier layer BL1 and the second barrier layer BL2 may each include Ti₆₅Zr₁₆Si₁₅Mo₄. According to an embodiment, the first barrier layer BL1 and the second barrier layer BL2 may each include a quaternary alloy composition having molybdenum (Mo) as a main element. For example, the first barrier layer BL1 and the second barrier layer BL2 may each include Ti₅₂Mo₅₂Zr₂₆Si₁₂Ti₁₀.

According to an embodiment, the first barrier layer BL1 and the second barrier layer BL2 may each include a ternary alloy composition having zirconium (Zr) as a main element. For example, the first barrier layer BL1 and the second barrier layer BL2 may each include Zr₇₄Cu₂₀Co₆ or Zr_{87.5}Cu₅Si_{7.5}. According to an embodiment, the first barrier layer BL1 and the second barrier layer BL2 may each include a quaternary alloy composition having aluminum (Al) as a main element or a binary alloy composition having aluminum (Al) as a main element. For example, the first barrier layer BL1 and the second barrier layer BL2 may each include Al₈₅Y₈Ni₅Co₂ or Al₉₀Y₁₀.

According to an embodiment, a thickness of the first barrier layer BL1 may be 50 nanometers (nm) to 70 nm, and a thickness of the second barrier layer BL2 may be 20 nm to 40 nm. When the thicknesses of the first barrier layer BL1 and the second barrier layer BL2 are less than 20 nm, it may be difficult to form an interface between the insulating layer and the first conductive layer CDL1, and, when the thicknesses of the first barrier layer BL1 and the second barrier layer BL2 exceed 70 nm, resistance of the connection wiring WL may increase and residue may remain during an etching process.

According to an embodiment, a thickness of the first conductive layer CDL1 may be 200 nm to 900 nm, and a thickness of each of the amorphous sublayer AL and the crystalline sublayer CL may be 40 nm to 80 nm. In this case, as shown in FIGS. 10A through 10C, the thicknesses of the amorphous sublayer AL and the crystalline sublayer CL may be determined according to the number of sublayers included in the first conductive layer CDL1. When the thickness of the first conductive layer CDL1 is less than 200 nm, RC delay due to the connection wiring WL may increase, and, when the thickness of the first conductive layer CDL1 exceeds 900 nm, a problem such as warping of a substrate may occur.

In conclusion, the display apparatus according to an embodiment of the disclosure may secure both high stretchability and high conductivity of the connection wiring WL through the first conductive layer CDL1 having an amorphous-crystalline multilayer structure, and may also increase the elastic strain limit of the connection wiring WL through the first barrier layer BL1 and the second barrier layer BL2 composed of amorphous alloys, thereby efficiently improving the reliability of the display apparatus.

FIG. 11 is a cross-sectional view of a connection electrode of a display apparatus according to an embodiment of the disclosure.

Referring to FIG. 11, a connection electrode CM may have a triple-layer structure. The connection electrode CM may refer to the first connection electrode CM1 disposed between the first organic insulating layer 119 of FIG. 9 and the second organic insulating layer 121 of FIG. 9 or the second connection electrode CM2 disposed between the second organic insulating layer 121 of FIG. 9 and the third organic insulating layer 123 of FIG. 9. The source electrode SE of FIG. 9, and the drain electrode DE of FIG. 9 arranged in the first island portion 11 of FIG. 9 may have the same structure and the same material as the connection electrode CM. The source electrode SE of FIG. 9 and the drain electrode DE of FIG. 9 may refer to some of the electrodes included in the thin film transistor TFT of FIG. 9 of the first island portion 11 of FIG. 9. For convenience of explanation, the following explanation focuses on the connection electrode CM.

According to an embodiment, the connection electrode CM may include a third barrier layer BL3, a second conductive layer CDL2 disposed on the third barrier layer BL3, and a fourth barrier layer BL4 disposed on the second conductive layer CDL2. However, the connection electrode CM may include a different material from the connection wiring WL, even though the connection electrode CM is disposed on the same layer as a layer on which the connection wiring WL is disposed.

According to an embodiment, the third barrier layer BL3, the second conductive layer CDL2, and the fourth barrier layer BL4 may each be composed of a single element rather than an alloy layer, and may include a crystalline metal. For example, the second conductive layer CDL2 may include pure aluminum (Al), and the third barrier layer BL3 and the fourth barrier layer BL4 may include pure titanium (Ti). A pure aluminum (Al) layer or a pure titanium (Ti) layer, which is a crystalline metal layer, may have a low elastic strain rate due to easy occurrence of cracks on a surface, but may have high electrical conductivity. Accordingly, the connection electrode CM (or the source electrode and the drain electrode) composed of Ti/Al/Ti may have a relatively low elastic strain limit compared to the connection wiring WL, but may have excellent electrical characteristics, so that power consumption of the display apparatus may be reduced.

As described above, when the display apparatus is stretched, higher strain may occur in the first bridge portion 12 of FIG. 9 than in the first island portion 11 of FIG. 9. That is, the connection wiring WL disposed in the first bridge portion 12 of FIG. 9, which is a high-strain portion, includes a barrier layer of an amorphous metal and a conductive layer of an amorphous-crystalline multilayer structure, thereby increasing the elastic strain limit of the connection wiring WL and improving the stretchability of the display apparatus. On the other hand, the connection electrode CM (or the source electrode and the drain electrode) disposed in the first island portion 11 of FIG. 9, which is a low-strain portion, includes crystalline metal layers, thereby improving the electrical characteristics of the pixel driving circuit portion PC of FIG. 9. In conclusion, as an electrode disposed in the first island portion 11 of FIG. 9 and wiring disposed in the first bridge portion 12 of FIG. 9 include different materials, the stretchability of the display apparatus may be improved, and also power consumption may be reduced.

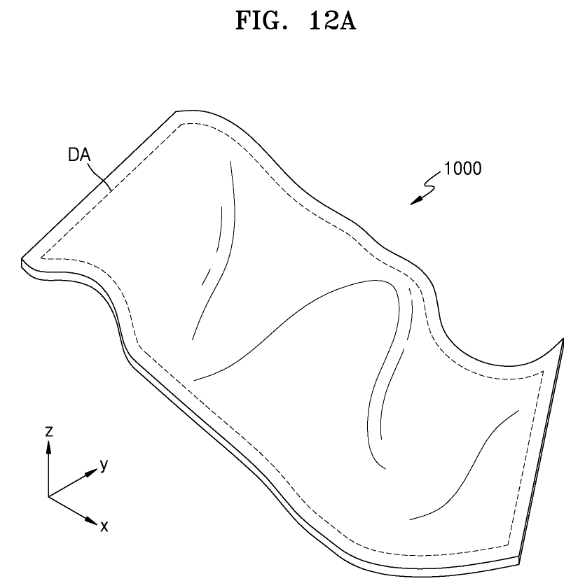

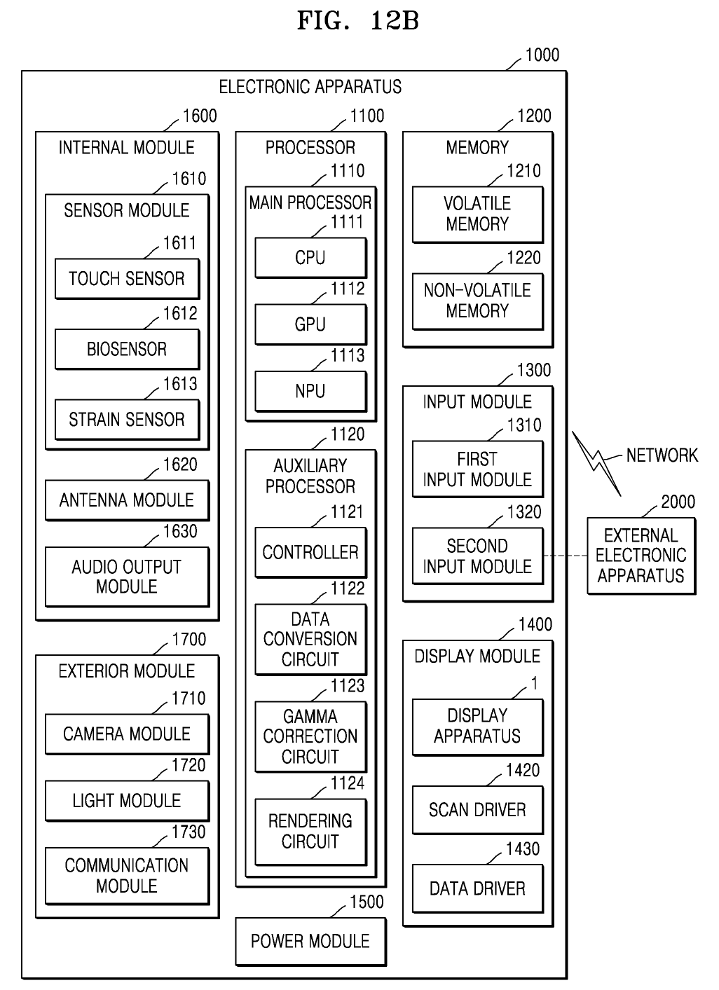

FIG. 12A is a schematic perspective view of an electronic apparatus 1000 including a display apparatus according to an embodiment of the disclosure, and FIG. 12B is a schematic block diagram of the electronic apparatus 1000 including the display apparatus 1 according to an embodiment of the disclosure.

Referring to FIG. 12A, the electronic apparatus 1000 may be freely transformed three-dimensionally, and may provide a three-dimensional image surface through the display area DA. The electronic apparatus 1000 being freely three-dimensionally transformed is distinguished from an operation of an electronic apparatus including a rollable display apparatus, such as a case where a portion of a rolled-up display area is visible to a user and then another portion of the rolled-up display area is unfolded and the entire display area is visible to the user (or a case where the entire unfolded display area is visible to the user and only a portion of the display area is visible to the user as the display area is g rolled up). The electronic apparatus 1000 according to embodiments of the disclosure may exhibit deformation such as the area of the entire display area DA increasing or decreasing again while the electronic apparatus 1000 is being deformed in an x-direction, a y-direction, and/or a z-direction.

Referring to FIG. 12B, the electronic apparatus 1000 may include a processor 1100, a memory 1200, an input module 1300, a display module 1400, a power module 1500, an internal module 1600, and an external module 1700. According to an embodiment, at least one of the above-described components of the electronic apparatus 1000 may be omitted, or one or more other components may be added to the electronic apparatus 1000. According to an embodiment, some of the above-described components (e.g., the internal module 1600) may be integrated into another component (e.g., the display module 1400).

The processor 1100 may execute software to control at least one other component (e.g., a hardware or software component) of the electronic apparatus 1000 connected to the processor 1100, and may perform various data processing or computations. According to an embodiment, as at least portion of data processing or computation, the processor 1100 may store a command or data received from another component (e.g., the input module 1300, a sensor module 1610, or a communication module 1730) in volatile memory 1210, process the command or data stored in the volatile memory 1210, and store resulting data in non-volatile memory 1220.

The processor 1100 may include a main processor 1110 and an auxiliary processor 1120. The main processor 1110 may include at least one of a central processing unit (CPU) or an application processor (AP). The main processor 1110 may further include at least one of a graphics processing unit (GPU), a communication processor (CP), or an image signal processor (ISP). The main processor 1110 may further include a neural processing unit (NPU) 1113. The NPU is a processor specialized in processing an artificial intelligence (AI) model, and the AI model may be created through machine learning. The AI model may include a plurality of artificial neural network layers. An artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the aforementioned networks, but is not limited to the above-described examples. The AI model may additionally or alternatively include a software structure in addition to a hardware structure. At least two of the aforementioned processing units and processors may be implemented as a single integrated configuration (e.g., a single chip) or may be implemented as independent configurations (e.g., a plurality of chips).

The auxiliary processor 1120 may include a controller 1121. The controller 1121 may include an interface conversion circuit and a timing control circuit. The controller 1121 receives an image signal from the main processor 1110, and converts a data format of the image signal according to interface specifications with the display module 1400 to thereby output image data. The controller 1121 may output various control signals necessary for driving the display module 1400.

The auxiliary processor 1120 may further include data processing circuits, such as a data conversion circuit 1122, a gamma correction circuit 1123, and a rendering circuit 1124. The data conversion circuit 1122 may receive the image data from the controller 1121, and may compensate for the image data so that an image is displayed with a desired brightness according to, for example, characteristics of the electronic apparatus 1000 or a user's settings, or may convert the image data to perform, for example, power consumption reduction or afterimage compensation. The gamma correction circuit 1123 may convert image data or a gamma reference voltage, etc.so that an image displayed on the electronic apparatus 1000 has desired gamma characteristics. The rendering circuit 1124 may receive the image data from the controller 1121, and may render the image data according to a pixel layout, etc. of the display apparatus 1 that are applied to the electronic apparatus 1000. At least one of the data conversion circuit 1122, the gamma correction circuit 1123, or the rendering circuit 1124 may be integrated into another component (e.g., the main processor 1110 or the controller 1121). According to an embodiment, the auxiliary processor 1120 may be integrated into a data driver 1430.

The memory 1200 may store various data used by at least one component of the electronic apparatus 1000 (e.g., the processor 1100 or the sensor module 1610) and input data or output data for commands associated with the various data. The memory 1200 may include at least one of the volatile memory 1210 or the non-volatile memory 1220.

The input module 1300 may receive commands or data that are to be used by components of the electronic apparatus 1000 (e.g., the processor 1100, the sensor module 1610, or the audio output module 1630) from an external source of the electronic apparatus 1000 (e.g., the user or an external electronic apparatus 2000).

The input module 1300 may include a first input module 1310 to which a command or data is input by the user, and a second input module 1320 to which a command or data is input by the external electronic apparatus 2000.

The first input module 1310 may include a microphone, a mouse, a keyboard, or a pen (e.g., a passive pen or an active pen). The first input module 1310 may include a mechanical input unit, such as a button, a dome switch, a jog wheel, and a jog switch each located on a rear or lateral surface of the electronic apparatus 1000, or a touch input unit. The touch input unit may include a touch screen layer of the display apparatus 1.

The second input module 1320 may be connected to various types of external electronic apparatuses 2000 connected to the electronic apparatus 1000 in a wired or wireless manner. According to an embodiment, the second input module 1320 may include a high definition multimedia interface (HDMI), a universal serial bus (USB) interface, a secure digital (SD) card interface, or an audio interface. The second input module 1320 may include a connector capable of physically connecting the electronic apparatus 1000 to the external electronic apparatus 2000, for example, an HDMI connector, a USB connector, an SD card connector, or an audio connector (e.g., a headphone connector). When the external electronic apparatus 2000 is connected to the second input module 1320, the electronic apparatus 1000 may perform an appropriate control related with the connected external electronic apparatus 2000.

The display module 1400 visually provides information to the user. The display module 1400 may include the display apparatus 1, a scan driver 1420, and a data driver 1430.

The display apparatus 1 displays (outputs) information that is processed by the electronic apparatus 1000. The display apparatus 1 may display execution screen information of an application being driven by the electronic apparatus 1000, or may display user interface (UI) and graphical user interface (GUI) information based on the execution screen information.

The scan driver 1420 may be mounted as a driving chip on the display apparatus 1. Alternatively, the scan driver 1420 may be directly formed on the display apparatus 1. For example, the scan driver 1420 may include an Amorphous Silicon TFT Gate (ASG) driver circuit, a Low Temperature Polycrystaline Silicon (LTPS) TFT gate driver circuit, or an Oxide Semiconductor TFT Gate (OSG) driver circuit embedded in the display apparatus 1. The scan driver 1420 receives a control signal from the controller 1121 and outputs scan signals to the display apparatus 1 in response to the control signal.

The display apparatus 1 may further include a light-emission control driver. The light-emission control driver outputs a light-emission control signal to the display apparatus 1 in response to the control signal received from the controller 1121. The light-emission control driver may be formed separately from the scan driver 1420 or may be integrated into the scan driver 1420.

The data driver 1430 receives a control signal from the controller 1121, convert image data into a data voltage in the form of an analog voltage in response to the control signal, and then output data voltages to the display apparatus 1.

The data driver 1430 may be integrated with some components of the auxiliary processor 1120. . The data driver 1430 may be included as a timing controller embedded driver IC including the controller 1121.

The data driver 1430 may be mounted as a driving chip on the display apparatus 1. Alternatively, the data driver 1430 may be directly formed on the display apparatus 1. When the scan driver 1420 and the data driver 1430 are formed directly on the display apparatus 1, the display apparatus 1 may be practically considered the display module 1400.

The power module 1500 supplies power to components of the electronic apparatus 1000. The power module 1500 may include a battery that charges a power supply voltage. The power module 1500 may also include a connection port, and the connection port may be included in the second input module 1320 to which an external charger supplying power to charge the battery is connected. Alternatively, the power module 1500 may include a wireless power transmission/reception member to charge the battery wirelessly. The wireless power transmission/reception member may include a plurality of coil-type antenna radiators. The power module 1500 may include a power management integrated circuit (PMIC). The PMIC provides optimized power to each of the components of the electronic apparatus 1000.

The electronic apparatus 1000 may further include the internal module 1600 and the external module 1700. The internal module 1600 may include a sensor module 1610, an antenna module 1620, and an audio output module 1630. The external module 1700 may include a camera module 1710, a light module 1720, and a communication module 1730.

The sensor module 1610 may include touch electrodes and a touch sensor driving unit of a touch screen layer of the display apparatus 1. The sensor module 1610 may detect an input froma user's body or a pen input, and may generate an electric signal or data value corresponding to the input. The sensor module 1610 may include at least one of a touch sensor 1611, a biosensor 1612, or a strain sensor 1613.

The touch sensor 1611 may generate a data value corresponding to coordinate information of the input from the user's body (e.g., a finger) or the pen input. The touch sensor 1611 may generate a data value based on an amount of change in capacitance, pressure, or electromagnetism due to the input.

The biosensor 1612 may generate data values that recognize parts of the user's body (e.g., fingerprints, irises, and a face) or generate data values corresponding to body information (e.g., a blood pressure, a moisture, a heart rate, and a body composition). The biosensor 1612 may use an optical method, an ultrasonic method, or a capacitive method.

The strain sensor 1613 may include a layer, a pattern or wirings in which a measurable physical quantity changes according to stretching of the display apparatus 1. For example, the strain sensor 1613 may include a layer, a pattern or wirings in which pressure, resistance, and/or capacitance changes according to stretching of the display apparatus 1. According to another embodiment, the strain sensor 1613 may include an optical layer or optical pattern in which transmittance and/or reflectance changes according to stretching of the display apparatus 1.

Based on a change in physical quantity due to the stretching of the display apparatus 1 measured by the strain sensor 1613, the electronic apparatus 1000 may improve the image quality of an image realized by the display apparatus 1 or may control the display apparatus 1. A control operation of the display apparatus 1 may include, for example, an operation of displaying an operation image for protecting the display apparatus 1, cutting off a voltage for driving the display apparatus 1, or stopping a stretching operation of the display apparatus 1.

According to an embodiment, at least one of the touch sensor 1611, the biosensor 1612, or the strain sensor 1613 may be built in the display apparatus 1. For example, at least one of the touch sensor 1611, the biosensor 1612, or the strain sensor 1613 may be formed via a process that is continuous with a process of forming the pixel driving circuit portions and light-emitting elements of the display apparatus 1. Accordingly, the display apparatus 1 may function as one of the input modules 1300 providing input interfaces between the electronic apparatus 1000 and a user, and also function as the output module providing an output interface between the electronic apparatus 1000 and the user.

According to another embodiment, at least two of the touch sensor 1611, the biosensor 1612, and the strain sensor 1613 may be formed to be integrated into one sensing panel via the same process. According to an embodiment, the sensing panel may be disposed between the display apparatus 1 and a window cover placed on a front surface of the display apparatus 1, but the disclosure is not limited thereto.

The antenna module 1620 may include one or more antennas for transmitting signals or power to the outside or receiving signals or power from the outside. According to an embodiment, the communication module 1730 may transmit a signal to an external electronic apparatus or receive a signal from the external electronic apparatus, through an antenna suitable for a communication method. An antenna pattern of the antenna module 1620 may be integrated into one component of the display module 1400 (e.g., the display apparatus 1) or into the sensor module 1610.

The audio output module 1630, which is a device for outputting an audio signal to the outside of the electronic apparatus 1000, may output audio data received from the communication module 1730 in a call signal reception mode, a call or recording mode, a voice recognition mode, a broadcast reception mode, etc. or stored in the memory 1200. The audio output module 1630 may output an audio signal related with a function (for example, a call signal receiving sound or a message receiving sound) performed by the electronic apparatus 1000. The audio output module 1630 may include a receiver and a speaker. A least one of the receiver and the speaker may be an audio generation device that is attached to a rear surface of the display apparatus 1 and vibrates the display apparatus 1 to output an audio. The audio generation device may be a piezoelectric element or piezoelectric actuator that shrinks and expands according to an electrical signal, or may be an exciter that generates a magnetic force by using a voice coil and vibrates the display apparatus 1.

The camera module 1710 may capture a still image and a video. According to an embodiment, the camera module 1710 may include one or more lenses, an image sensor, or an image signal processor. The camera module 1710 may further include an infrared camera capable of measuring presence or absence of a user, the user's location, the user's view, etc.

The light module 1720 may output a signal for notifying occurrence of an event by using light from a light source, or may provide light for image obtainment. Examples of the event occurrence may include message reception, call signal reception, a missed call, an alarm, schedule notification, e-mail reception, and notification of battery charging capacity information. The light module 1720 may include a light-emitting diode or a xenon lamp. The light module 1720 may emit light of a single color or light beams of a plurality of colors to a front surface or rear surface of the electronic apparatus 1000. The light module 1720 may operate in conjunction with the camera module 1710 or may operate independently.

The communication module 1730 may support establishment of a wired or wireless communication channel between the electronic apparatus 1000 and the external electronic apparatus 2000, and execution of communication through an established communication channel. The communication module 1730 may include one or both of a wireless communication module (such as, a cellular communication module, a short-range wireless communication module, or a global navigation satellite system (GNSS) communication module) and a wired communication module (such as, a local area network (LAN) communication module or a power line communication module). The communication module 1730 may transmit and receive a wireless signal on the Internet by using at least one of Wireless LAN (WLAN), Wireless-Fidelity (Wi-Fi), Wi-Fi Direct, or Digital Living Network Alliance (DLNA) technologies. The communication module 1730 may support short-distance communication by using at least one technology from among Bluetooth™, Radio Frequency Identification (RFID), Infrared Data Association (IrDA), Ultra-Wideband (UWB), ZigBee, Near Field Communication (NFC), Wi-Fi, Wi-Fi Direct, and Wireless Universal Serial Bus (Wireless USB). The aforementioned various types of communication modules 1730 may be implemented as one chip or as separate chips.

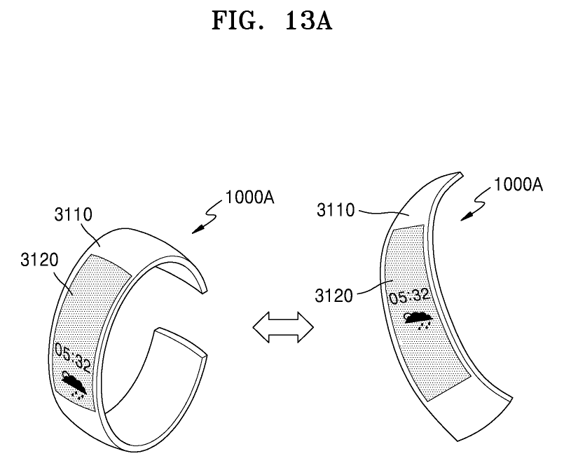

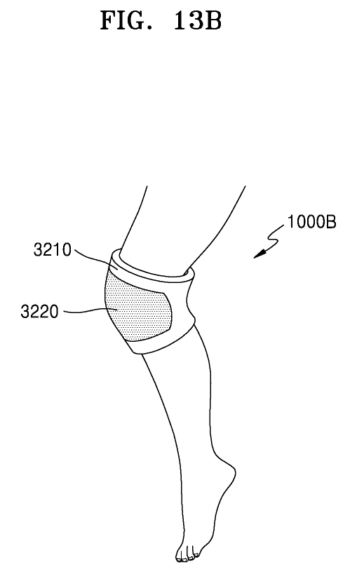

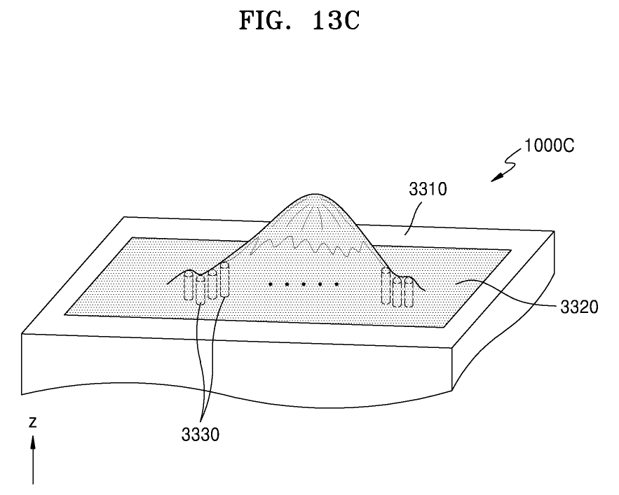

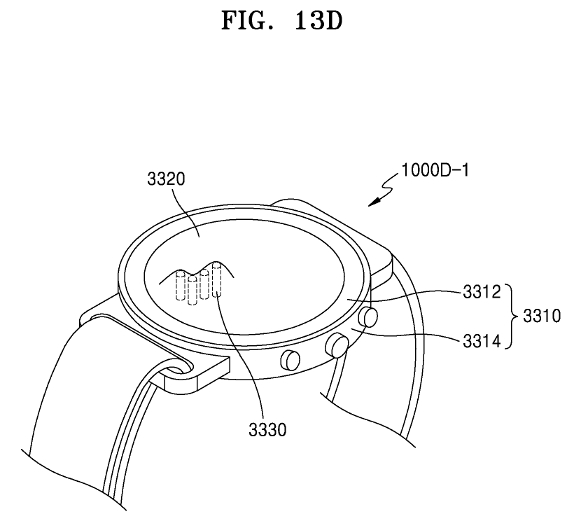

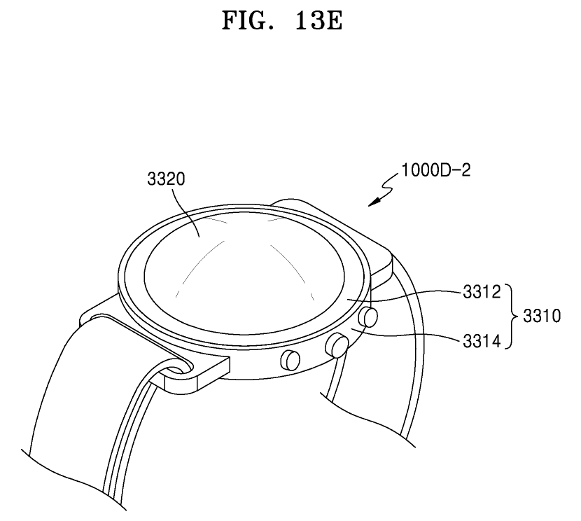

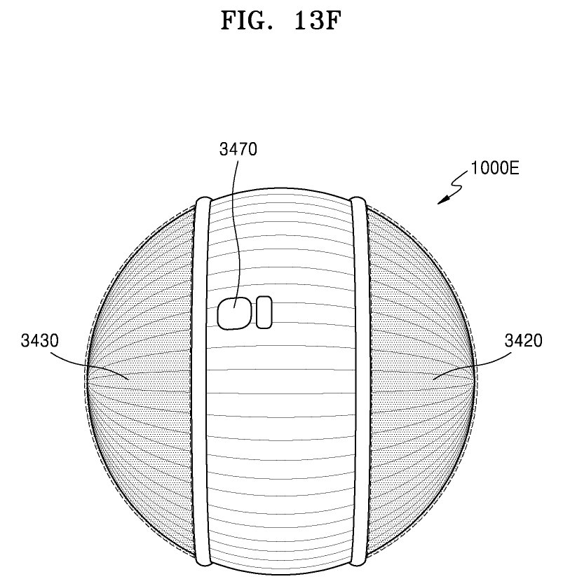

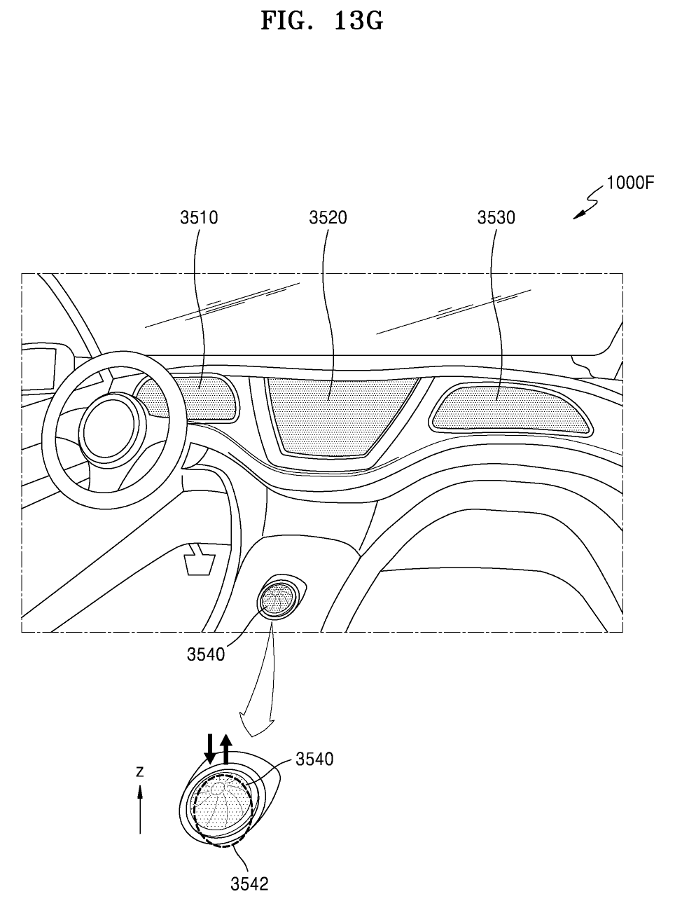

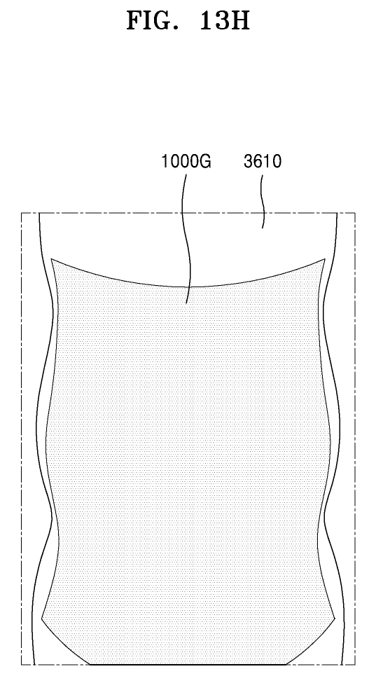

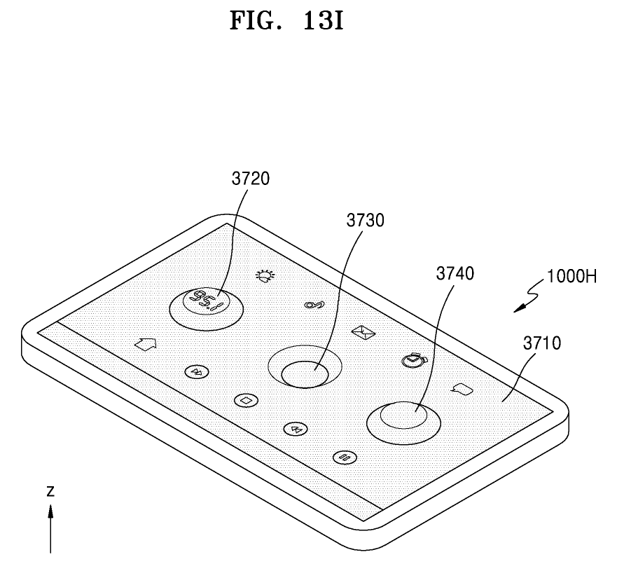

FIGS. 13A through 13I are schematic perspective views of embodiments of an electronic apparatus including a display apparatus according to an embodiment of the disclosure.

Referring to FIG. 13A, the display apparatus according to an embodiment of the disclosure may be utilized in a wearable electronic apparatus 1000A that may be worn on a portion of a user’s body. The wearable electronic apparatus 1000A may include a body portion 3110, and a display 3120 provided in the body portion 3110. The display apparatus according to embodiments of the disclosure may be used as the display 3120 of the wearable electronic apparatus 1000A. As shown in FIG. 13A, the wearable electronic apparatus 1000A may be transformed. According to an embodiment, the wearable electronic apparatus 1000A may be used as a smartwatch or a smartphone according to the user’s selection.

FIG. 13B shows a medical electronic apparatus 1000B. According to an embodiment, the medical electronic apparatus 1000B may include a body portion 3210 and an emission portion 3220. The display apparatus according to embodiments of the disclosure may be used as the emission portion 3220 of the medical electronic apparatus 1000B. The emission portion 3220 may be configured to emit light in a certain wavelength band (e.g., an infrared ray or a visible ray) to a patient’s body. According to an embodiment, the body portion 3210 may have a stretchable fiber material, and may have a structure that may be worn on the body of the user.

FIG. 13C shows an educational electronic apparatus 1000C. According to an embodiment, the educational electronic apparatus 1000C may include a display 3320 provided inside a body portion 3310. The display 3320 may use the display apparatus according to embodiments of the disclosure. Images such as sea with waves, a mountain covered with snow, or a volcano with flowing lava may be provided through the display 3320, and in this case, the display 3320 may extend in a height direction (e.g., a z direction) to reflect the height of waves, mountains, or volcanoes. According to some embodiments, because the height of a portion of the display 3320 sequentially varies in a direction in which the lava flows, the display 3320 may show the movements of lava three-dimensionally. The educational electronic apparatus 1000C may include a plurality of pins (or stroke portions) 3330 disposed on the backside of the display 3320 such that the display 3320 extends in the height direction. As the pins 3330 move in the third direction (e.g., a z direction or a -z direction), the image displayed on the display 3320 may be implemented to have a three-dimensional height. Although FIG. 13C describes the educational electronic apparatus 1000C, the purpose of the electronic apparatus is not limited as long as the electronic apparatus provides predetermined image information.

FIGS. 13D and 13E illustrate use of the display apparatus in wearable electronic apparatuses 1000D-1 and 1000D-2, such as smart watches.

According to an embodiment, as illustrated in FIG. 13D, the display apparatus corresponding to the display 3320 of the electronic apparatus 1000D-1 is three-dimensionally stretchable, so that various pieces of haptic information in addition to visual information may be provided to a user through an image. According to an embodiment, the electronic apparatus 1000D-1 may provide haptic information, such as a braille display for the visually impaired or tactile stimulation linked to an image, by using the plurality of pins (or stroke portions) 3330 arranged below the display 3320. Because the display apparatus forming the display 3320 is stretchable three-dimensionally, the display apparatus may provide the aforementioned haptic information to the user. The electronic apparatus 1000D-1 may include the display apparatus forming the display 3320, and a body portion 3310 including a housing 3314 in which the pins (or stroke portions) 3330 are accommodated, and a frame 3312 that may be coupled to the housing 3314 with the display apparatus interposed therebetween. According to some embodiments, the frame 3312 may be formed integrally with the housing 3314.

As shown in FIG. 13D, the electronic apparatus 1000D-2 of FIG. 13E may include a body portion 3310, and a display 3320 accommodated in the body portion 3310 and capable of providing visual information. According to some embodiments, because the display apparatus corresponding to the display 3320 is three-dimensionally stretchable, the display apparatus may include the display 3320 having a dome shape. According to an embodiment, a display apparatus may be assembled on a dome-shaped body frame in a manufacturing process of the electronic apparatus 1000D-2, and, at this time, because the display apparatus is three-dimensionally stretchable, the display apparatus may be assembled in a stretched state according to the shape of the hemispherical body frame.

FIG. 13F shows inclusion of a robot in an electronic apparatus 1000E according to an embodiment of the disclosure. The robot may recognize a move or an object by using the camera module 3470, and may display predetermined images to a user through displays 3420 and 3430.

According to some embodiments, because display apparatuses according to an embodiment of the disclosure are stretchable in various directions as described above, the display apparatuses may be assembled to a body frame having a hemispherical shape, and thus, the robot may include the displays 3420 and 3430 each having a hemispherical shape.

FIG. 13G shows a vehicle display apparatus 1000F as an electronic apparatus according to an embodiment of the disclosure. The vehicle display apparatus 1000F may include a cluster 3510, a center information display (CID) 3520, and/or a co-driver display 3530. Because the display apparatus according to an embodiment of the disclosure is stretchable in various directions, the display apparatus may be used as the cluster 3510, the CID 3520, and/or the co-driver display 3530 regardless of the shape of an internal frame of a vehicle.

Although it is shown in FIG. 13G that the cluster 3510, the CID 3520, and/or the co-driver display 3530 are separated from each other, the disclosure is not limited thereto. According to another embodiment, two or more selected from the cluster 3510, the CID 3520, and the co-driver display 3530 may be integrally connected to each other.

According to some embodiments, the vehicle display apparatus 1000F may include a button 3540 capable of displaying predetermined images. Referring to an enlarged view of FIG. 13G, the button 3540 having a hemispherical shape may include an object 3542 that provides the feeling of using the button while moving in the z direction or -z direction, and a display apparatus disposed on the object 3542. According to some embodiments, when the object 3542 has a surface rounded three-dimensionally, the display apparatus may also have a surface rounded three-dimensionally.

FIG. 13H shows that the electronic apparatus according to an embodiment of the disclosure is an electronic apparatus 1000G for advertising or exhibition. According to some embodiments, the electronic apparatus 1000G for advertising or exhibition may be provided on a structure 3610 that is fixed, such as on a wall or pillar. When the structure 3610 includes an uneven surface as shown in FIG. 13H, the electronic apparatus 1000G for advertising or exhibition may also be disposed along the uneven surface of the structure 3610. According to some embodiments, the electronic apparatus 1000G for advertising or exhibition may be provided on the structure 3610 by using a heat shrink film or the like.

FIG. 13I shows that an electronic apparatus 1000H according to an embodiment of the disclosure is a controller. The controller may include an image type button. For example, the controller may include first, second, and third bottom regions 3720, 3730, and 3740 in which a partial region of a display 3710 protrudes in a z direction or -z direction (or is recessed in the z direction). According to some embodiments, the first and third button regions 3720 and 3740 may each protrude in the z direction, and the second button region 3730 may protrude in the -z direction (or be recessed in the z direction).

While the disclosure has been described with reference to embodiments shown in the drawings, they are merely examples, and it will be understood by those of ordinary skill in the art that various changes in form and details may be made therein. Accordingly, the true technical protection scope of the disclosure should be determined by the technical spirit of the following claims.

### EXPLANATION OF REFERENCE CHARACTERS

1000: Electronic apparatus

1: Display apparatus

DA: Display area

NDA: Non-display area

PC: Pixel driving circuit portion

LED: Light-emitting element

11: First island portion

12: First bridge portion

WL: Connection wiring

CM: Connection electrode

BL1: First barrier layer

BL2: Second barrier layer

CDL1: First conductive layer

BL3: Third barrier layer

BL4: Fourth barrier layer

CDL2: Second conductive layer

What is claimed is:

1. A display apparatus including a display area and a non-display area surrounding the display area, the display apparatus comprising:
island portions spaced apart from each other in a first direction and a second direction intersecting the first direction in the display area and in which light-emitting elements are arranged;
bridge portions connecting two adjacent island portions among the island portions to each other; and
a connection wiring disposed on at least one bridge portion among the bridge portions,
wherein the connection wiring has a structure in which a first barrier layer, a first conductive layer disposed on the first barrier layer and a second barrier layer disposed on the first conductive layer are stacked, and
each of the first barrier layer and the second barrier layer includes an amorphous alloy.

2. The display apparatus of claim 1, wherein the amorphous alloys included in the first barrier layer and the second barrier layer include at least one of aluminum (Al), silicon (Si), titanium (Ti), cobalt (Co), nickel (Ni), copper (Cu), yttrium (Y), zirconium (Zr), or molybdenum (Mo).

3. The display apparatus of claim 1, wherein the amorphous alloys included in the first barrier layer and the second barrier layer include a binary to quaternary alloy composition having one of titanium (Ti), molybdenum (Mo), zirconium (Zr), and aluminum (Al) as a main element.

4. The display apparatus of claim 3, wherein the amorphous alloys included in the first barrier layer and the second barrier layer include at least one of Ti₆₅Zr₁₆Si₁₅Mo₄, Mo₅₂Zr₂₆Si₁₂Ti₁₀, Zr₇₄Cu₂₀Co₆, Zr_{87.5}Cu₅Si_{7.5} Al₈₅Y₈Ni₅Co₂, or Al₉₀Y₁₀.

5. The display apparatus of claim 1, wherein
the first conductive layer has a structure in which a first sublayer and a second sublayer are alternately stacked,
the first sublayer includes an amorphous alloy, and
the second sublayer includes a crystalline metal.

6. The display apparatus of claim 1, wherein the first sublayer and the second sublayer include materials based on same metals.

7. The display apparatus of claim 6, wherein the first sublayer includes an alloy of aluminum and a rare earth element, and the second sublayer includes aluminum.

8. The display apparatus of claim 7, wherein the rare earth element includes at least one of yttrium (Y), samarium (Sm), cerium (Ce), or lanthanum (La).

9. The display apparatus of claim 5, wherein a total number of first sublayers and second sublayers included in the first conductive layer is an odd number.

10. The display apparatus of claim 9, wherein an upper surface of the first barrier layer contacts the first sublayer, and a lower surface of the second barrier layer contacts the first sublayer.

11. The display apparatus of claim 1, further comprising:
a pixel driving circuit portion arranged on at least one island portion among the island portions and electrically connected to the light-emitting element; and
a connection electrode, which connects the pixel driving circuit portion to the light-emitting element,
wherein at least one of a source electrode and a drain electrode of the pixel driving circuit portion, or the connection electrode includes a different material from the connection wiring.

12. The display apparatus of claim 11, wherein
at least one of the source electrode, the drain electrode, or the connection electrode has a structure in which a third barrier layer, a second conductive layer on the third barrier layer, and a fourth barrier layer on the second conductive layer are stacked, and
the third barrier layer, the second conductive layer, and the fourth barrier layer are crystalline metal layers.

13. The display apparatus of claim 12, wherein each of the third barrier layer, the second conductive layer, and the fourth barrier layer is a single layer composed of a single element.

14. A display apparatus including a display area and a non-display area surrounding the display area, the display apparatus comprising:
island portions spaced apart from each other in the display area and in each of which a pixel driving circuit portion and a light-emitting element electrically connected to the pixel driving circuit portion are arranged;
bridge portions connecting two adjacent island portions among the island portions to each other;
a connection wiring disposed on at least one bridge portion among the bridge portions; and
a connection electrode disposed on at least one island portion among the island portions and which connects a corresponding pixel driving circuit portion to a corresponding light-emitting element,
wherein
the connection wiring has a structure in which a first barrier layer, a first conductive layer, and a second barrier layer are stacked,
the connection electrode has a structure in which a third barrier layer, a second conductive layer, and a fourth barrier layer are stacked, and
the first barrier layer and the second barrier layer of the connection wiring include amorphous alloys, and the third barrier layer and the fourth barrier layer of the connection electrode include crystalline metals.

15. The display apparatus of claim 14, wherein the amorphous alloys included in the first barrier layer and the second barrier layer include at least one of aluminum (Al), silicon (Si), titanium (Ti), cobalt (Co), nickel (Ni), copper (Cu), yttrium (Y), zirconium (Zr), or molybdenum (Mo).

16. The display apparatus of claim 14, wherein the amorphous alloys included in the first barrier layer and the second barrier layer include a binary to quaternary alloy composition having one of titanium (Ti), molybdenum (Mo), zirconium (Zr), and aluminum (Al) as a main element.

17. The display apparatus of claim 14, wherein
the first conductive layer has a structure in which a first sublayer and a second sublayer are alternately stacked,
the first sublayer includes an amorphous alloy, and
the second sublayer includes a crystalline metal.

18. The display apparatus of claim 17, wherein the first sublayer includes an alloy of aluminum and a rare earth element, and the second sublayer includes aluminum.

19. An electronic apparatus comprising:
a display apparatus, which provides an image; and
a housing in which the display apparatus is accommodated,
wherein
the display apparatus comprises:
island portions spaced apart from each other in a first direction and a second direction intersecting the first direction and in which light-emitting elements are arranged;
bridge portions connecting two adjacent island portions among the island portions to each other; and
a connection wiring disposed on at least one bridge portion among the bridge portions,
wherein the connection wiring has a structure in which a first barrier layer, a first conductive layer disposed on the first barrier layer, and a second barrier layer disposed on the first conductive layer are stacked, and
each of the first barrier layer and the second barrier layer includes an amorphous alloy.

20. The electronic apparatus of claim 19, wherein
the first conductive layer has a structure in which a first sublayer and a second sublayer are alternately stacked,
the first sublayer includes an amorphous alloy containing aluminum and a rare earth element, and
the second sublayer includes a crystalline metal containing aluminum.
